(19) United States
(12) Patent Application Publication
(10) Pub. No.: US 2024/0099113 A1
(43) Pub. Date: Mar. 21, 2024

(54) ELECTRONIC DEVICE

(71) Applicant: Samsung Display Co., LTD., Yongin-si (KR)

(72) Inventors: MINWOO WOO, Yongin-si (KR); SUNGHO KIM, Yongin-si (KR); SE WAN SON, Yongin-si (KR); SEUNGHYUN LEE, Yongin-si (KR); WANGWOO LEE, Yongin-si (KR); JISEON LEE, Yongin-si (KR); KYEONGWOO JANG, Yongin-si (KR); HYERI CHO, Yongin-si (KR)

(73) Assignee: Samsung Display Co., LTD., Yongin-si (KR)

(21) Appl. No.: 18/341,842

(22) Filed: Jun. 27, 2023

(30) Foreign Application Priority Data
Sep. 16, 2022 (KR) 10-2022-0116739

(51) Int. Cl. H10K 59/95; H10K 59/35

(52) U.S. Cl. CPC H10K 59/95; H10K 59/353

(57) ABSTRACT

An electronic device includes a display panel that includes a first region and a second region adjacent to the first region. The display panel includes a first light emitting unit that is disposed in the first region and that includes (1-1)th light emitting elements, (1-2)th light emitting elements, and (1-3)th light emitting elements and a second light emitting unit that is disposed in the first region and that includes (2-1)th light emitting elements, (2-2)th light emitting elements, and (2-3)th light emitting elements. The (1-1)th light emitting elements and the (2-1)th light emitting elements have the same arrangement pattern, the (1-3)th light emitting elements and the (2-3)th light emitting elements have the same arrangement pattern, and the (1-2)th light emitting elements and the (2-2)th light emitting elements have different arrangement patterns.

### CROSS-REFERENCE TO RELATED APPLICATION(S)

This application claims priority to and benefits of Korean Patent Application No. 10-2022-0116739 under 35 U.S.C. § 119, filed on Sep. 16, 2022, in the Korean Intellectual Property Office, the entire contents of which are incorporated herein by reference.

### BACKGROUND

Embodiments relate to an electronic device having improved product performance.

An electronic device may include various electronic parts such as a display panel, an electronic module, and the like. The electronic module may include a camera, an infrared sensor, a proximity sensor, or the like. The electronic module may be disposed under the display panel. A partial region of the display panel may have a higher transmittance than another partial region of the display panel. The electronic module may receive an external input through the partial region of the display panel, or may provide an output through the partial region of the display panel.

### SUMMARY

Embodiments provide an electronic device having improved product performance.

However, embodiments of the disclosure are not limited to those set forth herein. The above and other embodiments will become more apparent to one of ordinary skill in the art to which the disclosure pertains by referencing the detailed description of the disclosure given below.

According to an embodiment, an electronic device may include a display panel that includes a first region and a second region adjacent to the first region. The display panel may include a first light emitting unit that is disposed in the first region and that includes (1-1)th light emitting elements, (1-2)th light emitting elements, and (1-3)th light emitting elements and a second light emitting unit that is disposed in the first region and that includes (2-1)th light emitting elements, (2-2)th light emitting elements, and (2-3)th light emitting elements. The (1-1)th light emitting elements and the (2-1)th light emitting elements may have the same arrangement pattern, the (1-3)th light emitting elements and the (2-3)th light emitting elements may have the same arrangement pattern, and the (1-2)th light emitting elements and the (2-2)th light emitting elements may have different arrangement patterns.

The display panel may further include a (1-1)th pixel circuit electrically connected to the (1-1)th light emitting elements, a (1-2)th pixel circuit electrically connected to the (1-2)th light emitting elements, and a (1-3)th pixel circuit electrically connected to the (1-3)th light emitting elements.

The first region may include a first sub-region, a second sub-region that surrounds the first sub-region and has a light transmittance lower than a light transmittance of the first sub-region, a plurality of third sub-regions spaced apart from each other, the second sub-region between the plurality of third sub-regions, and a fourth sub-region that surrounds the second sub-region and the plurality of third sub-regions, and the second region may surround the fourth sub-region.

The first light emitting unit and the second light emitting unit may be disposed in the first sub-region, and the (1-1)th pixel circuit, the (1-2)th pixel circuit, and the (1-3)th pixel circuit may be disposed in the plurality of third sub-regions, respectively.

The first sub-region may include a first zone in which the first light emitting unit is disposed and a second zone in which the second light emitting unit is disposed.

The second zone may surround the first zone.

The display panel may further include a plurality of intermediate light emitting units disposed in the second sub-region, the plurality of third sub-regions, and the fourth sub-region, respectively. Each of the plurality of intermediate light emitting units may include (3-1)th light emitting elements, (3-2)th light emitting elements, and (3-3)th light emitting elements. The number of the (1-1)th light emitting elements may be equal to the number of the (3-1)th light emitting elements, and the number of the (1-3)th light emitting elements may be equal to the number of the (3-3)th light emitting elements. The number of the (1-2)th light emitting elements may be smaller than the number of the (3-2)th light emitting elements.

The display panel may further include a main light emitting unit disposed in the second region. The main light emitting unit may include first light emitting elements, second light emitting elements, and third light emitting elements, and the number of the second light emitting elements may be greater than the number of the (1-2)th light emitting elements.

The display panel may further include a plurality of main pixel circuits. The first light emitting elements, the second light emitting elements, and the third light emitting elements may be electrically connected to the plurality of main pixel circuits in a one-to-one manner.

A first point, a second point spaced apart from the first point in a first direction, a third point spaced apart from the first point in a second direction intersecting the first direction, a fourth point spaced apart from the third point in the first direction, a first selection point disposed between the first to fourth points, a second selection point spaced apart from the first selection point in the first direction, a third selection point spaced apart from the first selection point in the second direction, and a fourth selection point spaced apart from the third selection point in the first direction may be defined in each of the first light emitting unit and the second light emitting unit.

The (1-1)th light emitting elements may be disposed at the second point and the third point of the first light emitting unit. The (1-2)th light emitting elements may be disposed at two selection points selected from the first to fourth selection points of the first light emitting unit. The (1-3)th light emitting elements may be disposed at the first point and the fourth point of the first light emitting unit. The (2-1)th light emitting elements may be disposed at the second point and the third point of the second light emitting unit. The (2-2)th light emitting elements may be disposed at two selection points selected from the first to fourth selection points of the second light emitting unit. The (2-3)th light emitting elements may be disposed at the first point and the fourth point of the second light emitting unit.

The two selection points overlapping the (1-2)th light emitting elements may correspond to one of six combinations formed with the first to fourth selection points, and the two selection points overlapping the (2-2)th light emitting elements may correspond to another one of the six combinations.

The display panel may further include at least one of a third light emitting unit disposed in the first region, a fourth light emitting unit disposed in the first region, a fifth light emitting unit disposed in the first region, and a sixth light emitting unit disposed in the first region. An arrangement pattern of light emitting elements included in the third to sixth light emitting units may correspond to each of the remaining four combinations of the six combinations.

The (1-1)th light emitting elements and the (2-1)th light emitting elements may be red light emitting elements. The (1-2)th light emitting elements and the (2-2)th light emitting elements may be green light emitting elements. The (1-3)th light emitting elements and the (2-3)th light emitting elements may be blue light emitting elements.

The electronic device may further include a camera module disposed under the first region of the display panel, and a plurality of transmissive regions may be defined in the first region.

According to an embodiment, an electronic device may include a display panel that includes a first light emitting unit including six first arrangement light emitting elements and a second light emitting unit including six second arrangement light emitting elements. A first point, a second point spaced apart from the first point in a first direction, a third point spaced apart from the first point in a second direction intersecting the first direction, a fourth point spaced apart from the third point in the first direction, a first selection point defined between the first to fourth points, a second selection point spaced apart from the first selection point in the first direction, a third selection point spaced apart from the first selection point in the second direction, and a fourth selection point spaced apart from the third selection point in the first direction may be defined in each of the first light emitting unit and the second light emitting unit. Among the first arrangement light emitting elements, four first arrangement light emitting elements may be disposed at the first to fourth points, and two first arrangement light emitting elements may be disposed at two selection points of a first combination among the first to fourth selection points. Among the second arrangement light emitting elements, four second arrangement light emitting elements may be disposed at the first to fourth points, and two second arrangement light emitting elements may be disposed at two selection points of a second combination different from the first combination among the first to fourth selection points.

A first region and a second region adjacent to the first region and having a light transmittance lower than a light transmittance of the first region may be defined in the display panel. The first region may include a first sub-region, a second sub-region that surrounds the first sub-region and may have a light transmittance lower than a light transmittance of the first sub-region, a plurality of third sub-regions spaced apart from each other with the second sub-region therebetween, and a fourth sub-region that surrounds the second sub-region and the plurality of third sub-regions. The first light emitting unit and the second light emitting unit may be disposed in the first sub-region.

The first sub-region may include a first zone in which the first light emitting unit is disposed and a second zone in which the second light emitting unit is disposed.

The display panel may further include three first pixel circuits electrically connected to the first light emitting unit and three second pixel circuits electrically connected to the second light emitting unit, and the first pixel circuits and the second pixel circuits may be disposed in the plurality of third sub-regions, respectively.

The display panel may further include an intermediate light emitting unit that is disposed in the second sub-region, the plurality of third sub-regions, or the fourth sub-region and that includes eight intermediate light emitting elements and three third pixel circuits electrically connected to the intermediate light emitting unit.

According to an embodiment, an electronic device may include a display panel including a first region and a second region adjacent to the first region, and the first region may include a first sub-region including a transmissive region and a second sub-region spaced apart from the first sub-region. The display panel may include a first light emitting unit that is disposed in the first sub-region and that includes first green light emitting elements arranged according to a first arrangement pattern, a second light emitting unit that is disposed in the first sub-region and that includes second green light emitting elements arranged according to a second arrangement pattern different from the first arrangement pattern, a first pixel circuit disposed in the second sub-region and electrically connected to the first green light emitting elements, and a second pixel circuit disposed in the second sub-region and electrically connected to the second green light emitting elements.

The first light emitting unit may further include first blue light emitting elements and first red light emitting elements. The second light emitting unit may further include second blue light emitting elements and second red light emitting elements, the first blue light emitting elements and the second blue light emitting elements are arranged according to a same arrangement pattern, the first red light emitting elements and the second red light emitting elements are arranged according to a same arrangement pattern.

### BRIEF DESCRIPTION OF THE DRAWINGS

The above and other objects and features of the disclosure will become apparent by describing in detail embodiments thereof with reference to the accompanying drawings.

FIGS. 1A and 1B are schematic perspective views of an electronic device according to an embodiment.

FIG. 2A is a schematic exploded perspective view of the electronic device according to an embodiment.

FIG. 2B is a block diagram of the electronic device according to an embodiment.

FIG. 3 is a schematic sectional view of a display device according to an embodiment.

FIG. 4 is a schematic plan view of a display panel according to an embodiment.

FIG. 5 is a schematic diagram of an equivalent circuit of a pixel according to an embodiment.

FIG. 6 is a schematic enlarged plan view illustrating a partial region of the display panel according to an embodiment.

FIGS. 7A to 7F are schematic plan views illustrating light emitting units according to embodiments.

FIGS. 8A to 8C are schematic plan views illustrating first sub-regions according to embodiments.

FIG. 9 is a schematic plan view illustrating a light emitting unit according to an embodiment.

FIG. 10 is a schematic plan view illustrating a light emitting unit and pixel circuits according to an embodiment.

FIG. 11 is a schematic plan view illustrating a light emitting unit and pixel circuits according to an embodiment.

FIG. 12 is a schematic plan view illustrating a light emitting unit and pixel circuits according to an embodiment.

FIG. 13 is a schematic plan view illustrating a light emitting unit and pixel circuits according to an embodiment.

FIG. 14 is a schematic sectional view of the display panel according to an embodiment.

FIG. 15 is a schematic sectional view of the display panel according to an embodiment.

FIG. 16A is a schematic enlarged plan view illustrating a partial region of the display panel according to an embodiment.

FIG. 16B is a schematic enlarged plan view illustrating a partial region of the display panel according to an embodiment.

FIG. 17A is a schematic enlarged plan view illustrating a partial region of the display panel according to an embodiment.

FIG. 17B is a schematic enlarged plan view illustrating a partial region of the display panel according to an embodiment.

FIG. 17C is a schematic enlarged plan view illustrating a partial region of the display panel according to an embodiment.

FIG. 18 is a schematic plan view illustrating a step of a manufacturing method of the display panel according to an embodiment.

FIG. 19 is a schematic plan view for describing a random arrangement according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

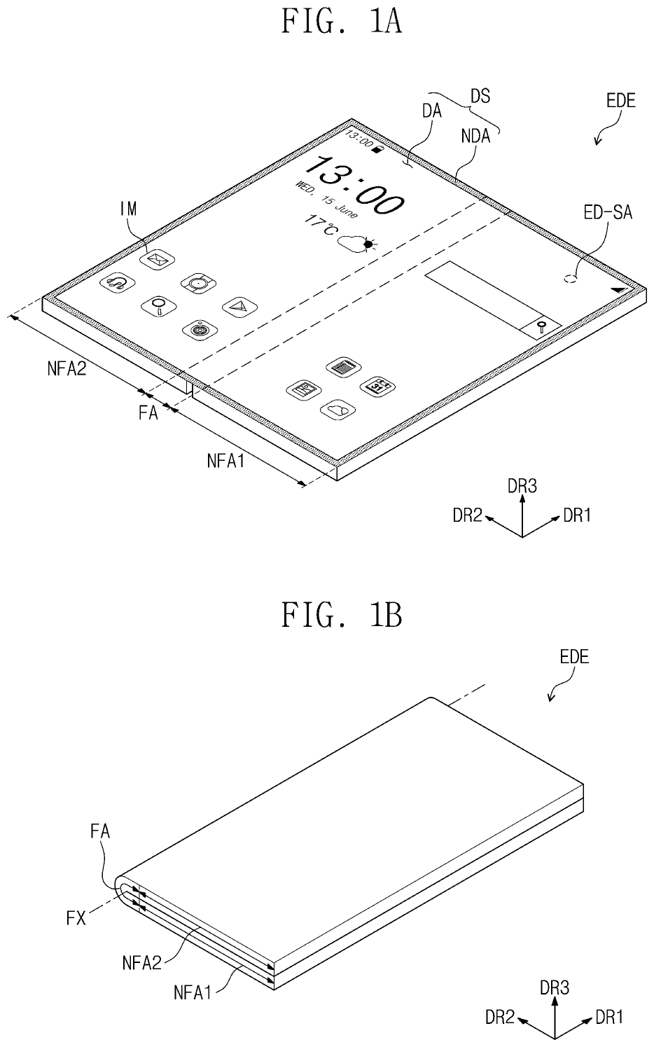

FIGS. 1A and 1B are schematic perspective views of an electronic device EDE according to an embodiment. FIG. 1A illustrates a flat state (or, an unfolded state) of the electronic device EDE, and FIG. 1B illustrates a folded state of the electronic device EDE.

Referring to FIGS. 1A and 1B, the electronic device EDE according to an embodiment may include a display surface DS defined by a first direction DR1 and a second direction DR2 intersecting the first direction DR1. The electronic device EDE may provide an image IM to a user through the display surface DS.

The display surface DS may include a display region DA and a non-display region NDA around the display region DA. The display region DA may display the image IM, and the non-display region NDA may not display the image IM. The non-display region NDA may surround the display region DA. However, the shape of the display region DA and the shape of the non-display region NDA may be modified. In another example, the non-display region NDA may be omitted.

Hereinafter, a direction substantially perpendicular to the plane defined by the first direction DR1 and the second direction DR2 is defined as a third direction DR3. For example, the expression “in plan view” used herein may mean that it is viewed in the third direction DR3.

A sensor region ED-SA may be defined in the display region DA of the electronic device EDE. Although a sensor region ED-SA is illustrated in FIG. 1A as an example, the number of the sensor regions ED-SA is not limited thereto. The sensor region ED-SA may be a portion of the display region DA. Accordingly, the electronic device EDE may display an image through the sensor region ED-SA.

An electronic module may be disposed in a region overlapping the sensor region ED-SA. The electronic module may receive an external input transferred through the sensor region ED-SA, or may provide an output through the sensor region ED-SA. For example, the electronic module may be a camera module, a sensor that measures a distance, such as a proximity sensor, a sensor that recognizes a part of the user's body (e.g., a fingerprint, an iris, or a face), or a small lamp that outputs light. However, embodiments are not limited thereto. Hereinafter, it will be described that the electronic module overlapping the sensor region ED-SA is a camera module.

The electronic device EDE may include a folding region FA and non-folding regions NFA1 and NFA2. The non-folding regions NFA1 and NFA2 may include the first non-folding region NFA1 and the second non-folding region NFA2. The folding region FA may be disposed between the first non-folding region NFA1 and the second non-folding region NFA2. The folding region FA may be referred to as a foldable region, and the first and second non-folding regions NFA1 and NFA2 may be referred to as first and second non-foldable regions.

As illustrated in FIG. 1B, the folding region FA may be folded about a folding axis FX parallel to the first direction DR1. The folding region FA may have a certain curvature and a certain radius of curvature in the folded state of the electronic device EDE. The electronic device EDE may be folded inward such that the first non-folding region NFA1 and the second non-folding region NFA2 may face each other and the display surface DS may not be exposed to the outside.

In an embodiment, the electronic device EDE may be folded outward such that the display surface DS may be exposed to the outside. In an embodiment, the electronic device EDE may be folded inward or outward in the flat state. However, embodiments are not limited thereto. In an embodiment, the electronic device EDE may select one of an unfolding operation, an in-folding operation, and an out-folding operation. In an embodiment, folding axes may be defined in the electronic device EDE, and the electronic device EDE may be folded inward or outward about the folding axes in the flat state.

Although the foldable electronic device EDE has been described as an example with reference to FIGS. 1A and 1B, embodiments are not limited to the foldable electronic device EDE. For example, the electronic device EDE may be implemented as a rigid electronic device, for example, an electronic device not including the folding region FA.

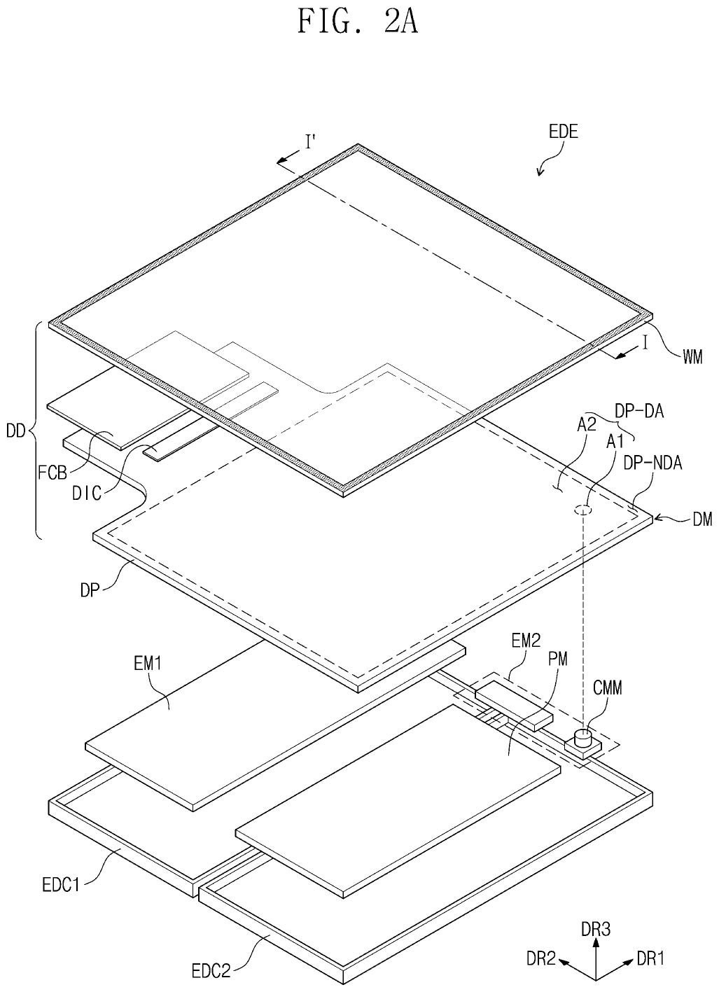

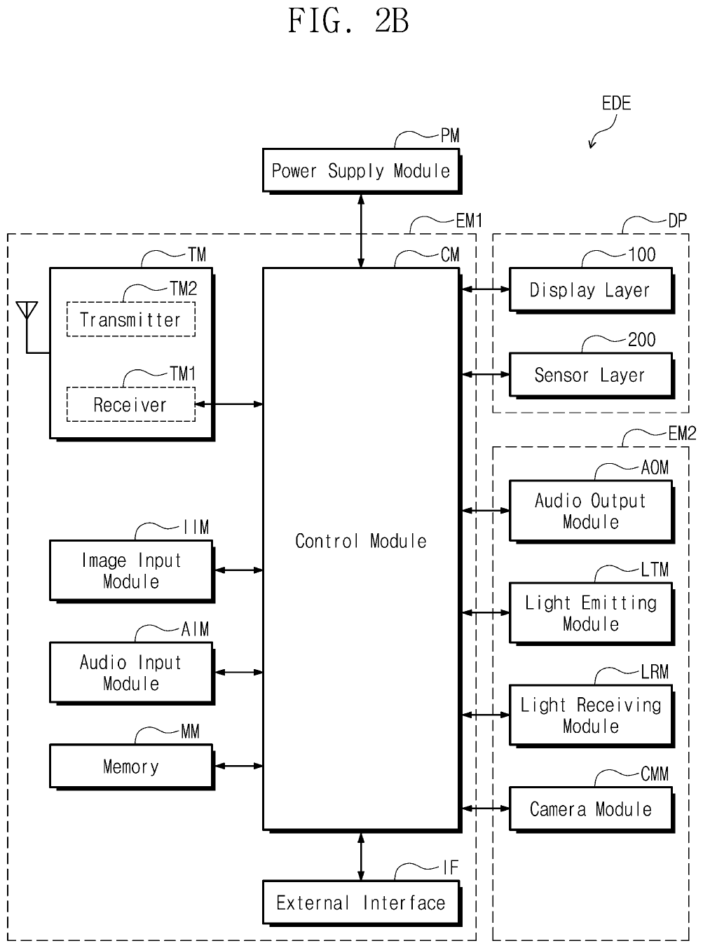

FIG. 2A is a schematic exploded perspective view of the electronic device EDE according to an embodiment. FIG. 2B is a schematic block diagram of the electronic device EDE according to an embodiment.

Referring to FIGS. 2A and 2B, the electronic device EDE may include a display device DD, a first electronic module EM1, a second electronic module EM2, a power supply module PM, and housings EDC1 and EDC2. The electronic device EDE may further include a mechanical structure for controlling a folding operation of the display device DD.

The display device DD may include a window module WM and a display module DM. The window module WM may form a front surface of the electronic device EDE. The display module DM may include at least a display panel DP. The display module DM may generate an image and detects an external input.

In FIG. 2, the display module DM is illustrated as being the same as the display panel DP. However, the display module DM may substantially be a stacked structure in which components including the display panel DP are stacked. The stacked structure of the display module DM will be described below in detail.

The display panel DP may include a display region DP-DA and a non-display region DP-NDA corresponding to the display region DA (refer to FIG. 1A) and the non-display region NDA (refer to FIG. 1A) of the electronic device EDE. The expression “one region/portion corresponds to another region/portion” used herein means that the regions/portions overlap each other and is not limited to having the same area.

The display region DP-DA may include a first region A1 and a second region A2. The first region A1 may overlap (or correspond to) the sensor region ED-SA (refer to FIG. 1A) of the electronic device EDE. Although the first region A1 is illustrated in a circular shape in this embodiment, the first region A1 may have various shapes, such as a polygonal shape, an oval shape, a shape having at least one curved side, or an irregular shape, and is not limited to any one embodiment. The first region A1 may be referred to as a component region, and the second region A2 may be referred to as a main display region or a normal display region.

At least a portion of the first region A1 may have a higher transmittance (or a higher light transmittance) than the second region A2. In another example, the first region A1 may have a lower resolution than the second region A2. However, embodiments are not limited thereto. For example, at least a portion of the first region A1 may have a higher transmittance (or a higher light transmittance) than the second region A2, but the resolution of the first region A1 may be substantially the same as the resolution of the second region A2. The first region A1 may overlap a camera module CMM to be described below.

The display panel DP may include a display layer 100 and a sensor layer 200.

The display layer 100 may be a component that substantially generates an image. The display layer 100 may be an emissive display layer. For example, the display layer 100 may be an organic light emitting display layer, an inorganic light emitting display layer, an organic-inorganic light emitting display layer, a quantum-dot display layer, a micro-LED display layer, or a nano-LED display layer.

The sensor layer 200 may sense an external input applied from the outside. The external input may be a user input. The user input may include various types of external inputs such as a part of the user's body, light, heat, a pen, or pressure.

The display module DM may include a driver integrated circuit (IC) DIC disposed on the non-display region DP-NDA. The display module DM may further include a flexible circuit film FCB coupled to the non-display region DP-NDA.

The driver IC DIC may include drive elements (e.g., a data drive circuit) for driving pixels of the display panel DP. Although FIG. 2A illustrates a structure in which the driver IC DIC is mounted on the display panel DP, embodiments are not limited thereto. For example, the driver IC DIC may be mounted on the flexible circuit film FCB.

The power supply module PM may supply power required for overall operation of the electronic device EDE. The power supply module PM may include a battery module.

The first electronic module EM1 and the second electronic module EM2 may include various functional modules for operating the electronic device EDE. The first electronic module EM1 and the second electronic module EM2 may be mounted (e.g., directly mounted) on a mother board electrically connected to the display panel DP, or may be mounted on separate substrates and may be electrically connected to the mother board through connectors.

The first electronic module EM1 may include a control module CM, a wireless communication module TM, an image input module IIM, an audio input module AIM, a memory MM, and an external interface IF.

The control module CM may control overall operation of the electronic device EDE. The control module CM may be a microprocessor. For example, the control module CM may activate or deactivate the display panel DP. The control module CM may control other modules, such as the image input module IIM or the audio input module AIM, based on a touch signal received from the display panel DP.

The wireless communication module TM may communicate with an external electronic device through a first network (e.g., a short-range communication network such as Bluetooth, WiFi direct, or infrared data association (IrDA)) or a second network (e.g., a long-range communication network such as a cellular network, Internet, or a computer network (e.g., LAN or WAN)). Communication modules included in the wireless communication module TM may be integrated into a component (e.g., a single chip), or may be implemented as components (e.g., chips) separated from one another. The wireless communication module TM may transmit/receive audio signals by using a general communication line. The wireless communication module TM may include a transmitter TM1 that modulates a signal to be transmitted and transmits the modulated signal and a receiver TM2 that demodulates a received signal.

The image input module IIM may process an image signal to covert the image signal into image data that are displayed on the display panel DP. The audio input module AIM may receive an external audio signal through a microphone in a voice recording mode or a voice recognition mode and may convert the external audio signal into electrical voice data.

The external interface IF may include a connector capable of physically connecting the electronic device EDE and an external electronic device. For example, the external interface IF may function as an interface between the control module CM and external devices, such as an external charger, a wired/wireless data port, a card (e.g., a memory card and a SIM/UIM card), etc.

The second electronic module EM2 may include an audio output module AOM, a light emitting module LTM, a light receiving module LRM, and the camera module CMM. The audio output module AOM may convert audio data received from the wireless communication module TM or audio data stored in the memory MM and may output the converted data to the outside.

The light emitting module LTM may generate and may output light. The light emitting module LTM may output infrared light. The light emitting module LTM may include an LED element. The light receiving module LRM may sense infrared light. The light receiving module LRM may be activated in case that infrared light above a certain level is sensed. The light receiving module LRM may include a CMOS sensor. Infrared light generated by the light emitting module LTM may be reflected by an external object (e.g., the user's finger or face), and the reflected infrared light may be incident on the light receiving module LRM.

The camera module CMM may take a still image and a moving image (e.g., video). Camera modules CMM may be provided (or implemented). A part of the camera modules CMM may overlap the first region A1. An external input (e.g., light) may be provided to the camera module CMM through the first region A1. For example, the camera module CMM may take an external image by receiving natural light through the first region A1.

The housings EDC1 and EDC2 may accommodate the display module DM, the first and second electronic modules EM1 and EM2, and the power supply module PM. The housings EDC1 and EDC2 may protect components, such as the display module DM, the first and second electronic modules EM1 and EM2, and the power supply module PM, which are accommodated in the housings EDC1 and EDC2. Although the two housings EDC1 and EDC2 separated from each other are illustrated in FIG. 2A as an example, embodiments are not limited thereto. For example, the electronic device EDE may further include a hinge structure for connecting the two housings EDC1 and EDC2. The housings EDC1 and EDC2 may be coupled to the window module WM.

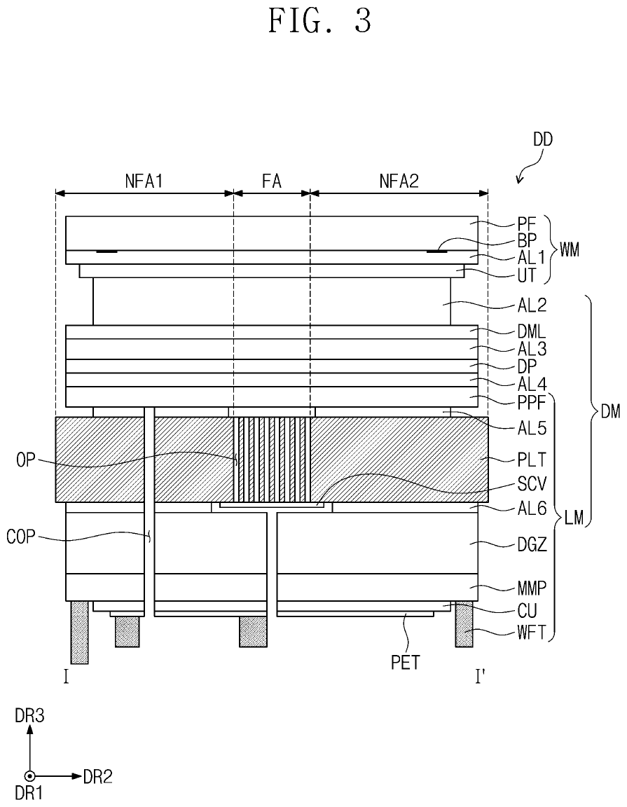

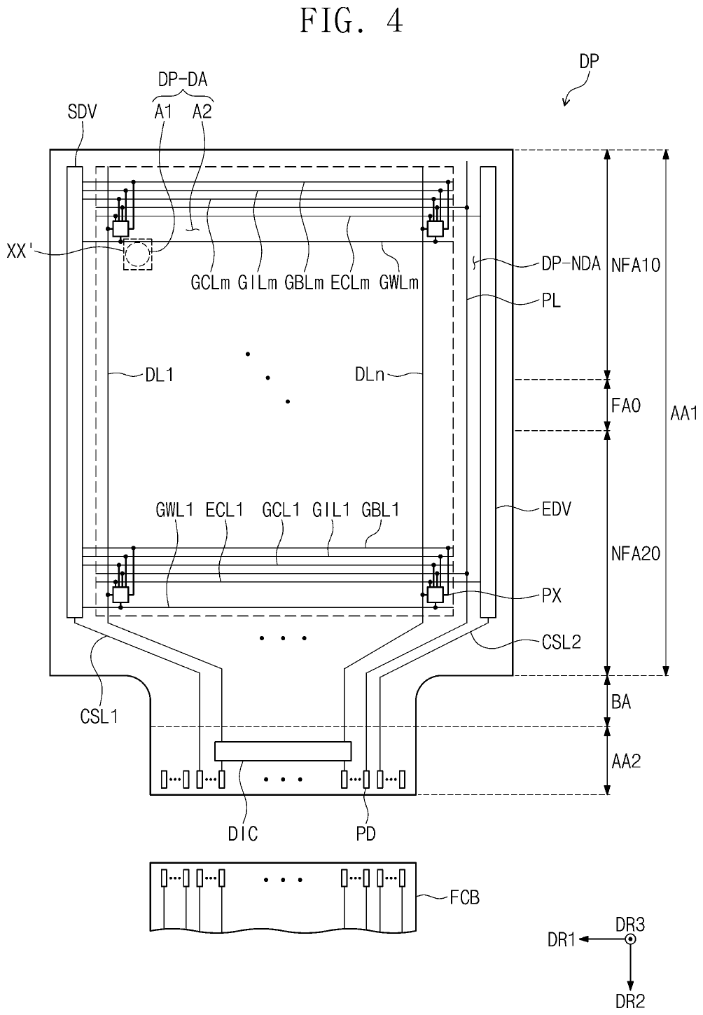

FIG. 3 is a schematic sectional view of the display device DD according to an embodiment. FIG. 3 is a schematic sectional view of the display device DD taken along line I-I′ of FIG. 2A according to an embodiment.

Referring to FIG. 3, the display device DD may include the window module WM and the display module DM.

The window module WM may include a window UT, a protective film PF disposed on the window UT, and a bezel pattern BP.

The window UT may be chemically strengthened glass. As the window UT is applied to the display device DD, a crease (or wrinkle) may be minimized although folding and unfolding operations are repeated.

The protective film PF may include polyimide, polycarbonate, polyamide, triacetylcellulose, polymethylmethacrylate, or polyethylene terephthalate. For example, at least one of a hard coating layer, an anti-fingerprint layer, and an anti-reflection layer may be disposed on an upper surface of the protective film PF.

The bezel pattern BP may overlap the non-display region NDA (refer to FIG. 1A). The bezel pattern BP may be disposed on a surface of the window UT or a surface of the protective film PF. In FIG. 3, the bezel pattern BP disposed on a lower surface of the protective film PF is illustrated as an example. However, embodiments are no limited thereto, and the bezel pattern BP may be disposed on the upper surface of the protective film PF, an upper surface of the window UT, or a lower surface of the window UT. The bezel pattern BP may be a colored light-blocking film and may be formed by, for example, a coating method. The bezel pattern BP may include a base material and a dye or pigment mixed in the base material. The bezel pattern BP may have a closed-line shape in plan view.

A first adhesive layer AL1 may be disposed between the protective film PF and the window UT. The first adhesive layer AL1 may be a pressure sensitive adhesive (PSA) film or an optically clear adhesive (OCA) member. Adhesive layers to be described below may also be the same as the first adhesive layer AL1 and may include an adhesive.

The first adhesive layer AL1 may have a thickness sufficient to cover the bezel pattern BP. For example, the bezel pattern BP may have a thickness in a range of about 3 micrometers to about 8 micrometers, and the first adhesive layer AL1 may have a thickness at a level at which bubbles are not generated around the bezel pattern BP.

The first adhesive layer AL1 may be separated from the window UT. The protective film PF may be relatively readily scratched since the protective film PF has a lower strength than the window UT. After the first adhesive layer AL1 and the damaged protective film PF are separated from the window UT, a new protective film PF may be attached to the window UT.

The display module DM may include an impact absorbing layer DML, the display panel DP, and a lower member LM.

The impact absorbing layer DML may be disposed on the display panel DP. The impact absorbing layer DML may be a functional layer for protecting the display panel DP from an external impact. The impact absorbing layer DML may be coupled to the window UT through a second adhesive layer AL2 and may be coupled to the display panel DP through a third adhesive layer AL3.

The lower member LM may be disposed under the display panel DP. The lower member LM may include a panel protection layer PPF, a support layer PLT, a cover layer SCV, a digitizer DGZ, a shielding layer MMP, a heat radiating layer CU, a protective layer PET, and a waterproof tape WFT. In an embodiment, the lower member LM may not include some of the aforementioned components, or may further include other components. Furthermore, the stacking sequence illustrated in FIG. 3 is an example, and the sequence in which the components are stacked may be changed.

The panel protection layer PPF may be disposed under the display panel DP. The panel protection layer PPF may be attached to a rear surface of the display panel DP through a fourth adhesive layer AL4. The panel protection layer PPF may protect a lower portion of the display panel DP. The panel protection layer PPF may include a flexible plastic material. The panel protection layer PPF may prevent a scratch on the rear surface of the display panel DP during a manufacturing process of the display panel DP. The panel protection layer PPF may be a colored polyimide film. For example, the panel protection layer PPF may be an opaque yellow film, but embodiments are not limited thereto.

The support layer PLT may be disposed under the panel protection layer PPF. The support layer PLT may support components disposed on the upper side of the support layer PLT and may maintain a flat state (or unfolded state) and a folded state of the display device DD. In an embodiment, the support layer PLT may include at least a first support portion corresponding to (or disposed in) the first non-folding region NFA1, a second support portion corresponding to (or disposed in) the second non-folding region NFA2, and a folding portion corresponding to (or disposed in) the folding region FA. The first support portion and the second support portion may be spaced apart from each other in the second direction DR2. The folding portion may be disposed between the first support portion and the second support portion, and openings OP may be formed in the folding portion. The flexibility of a portion of the support layer PLT may be improved by the openings OP. The flexibility of the portion of the support layer PLT that overlaps the folding region FA may be improved by the openings OP.

The support layer PLT may include carbon fiber reinforced plastic (CFRP), but embodiments are not limited thereto. In another example, the first support portion and the second support portion may include a non-metallic material, plastic, glass fiber reinforced plastic, or glass. The plastic may include polyimide, polyethylene, or polyethylene terephthalate, but embodiments are not limited. The first support portion and the second support portion may include the same material. The folding portion may include a material that is the same as (or different from) that of the first support portion and the second support portion. For example, the folding portion may include a material having an elastic modulus of about 60 GPa or more and may include a metallic material such as stainless steel. For example, the folding portion may include SUS 304. However, without being limited thereto, the folding portion may include various metallic materials.

The support layer PLT may be attached to the panel protection layer PPF through a fifth adhesive layer AL5. Fifth adhesive layers AL5 may be provided. The fifth adhesive layers AL5 may be spaced apart from each other with the folding region FA therebetween. The fifth adhesive layer AL5 may not overlap the openings OP. Furthermore, in plan view, the fifth adhesive layer AL5 may be spaced apart from the openings OP. The flexibility of the support layer PLT may be improved since the fifth adhesive layer AL5 is not disposed in a region corresponding to the folding region FA.

In a region overlapping the folding region FA, the panel protection layer PPF may be spaced apart from the support layer PLT. For example, in a portion overlapping the folding region FA, an empty space may be formed between the support layer PLT and the panel protection layer PPF. Since the empty space is formed between the panel protection layer PPF and the support layer PLT, the shape of the openings OP formed in the support layer PLT may not be visible from outside the electronic device EDE (refer to FIG. 1A).

The fifth adhesive layer AL5 may have a smaller thickness than the fourth adhesive layer AL4. For example, the fourth adhesive layer AL4 may have a thickness of about 25 micrometers, and the fifth adhesive layer AL5 may have a thickness of about 16 micrometers. As the thickness of the fifth adhesive layer AL5 is decreased, a step difference caused by the fifth adhesive layer AL5 may be decreased. As the step difference is decreased, deformation of stacked structures due to folding and unfolding operations of the electronic device EDE (refer to FIG. 1A) may be reduced. However, the openings OP may be visible, or the fifth adhesive layer AL5 may be separated by repeated folding operations. As the thickness of the fifth adhesive layer AL5 is increased, the openings OP may not be visible, and the reliability with respect to an adhesive force of the fifth adhesive layer AL5 may be improved in spite of the repeated folding operations, however, the step difference may increase. However, the step difference may be increased. Accordingly, the thickness of the fifth adhesive layer AL5 may be selected within an appropriate range in consideration of folding reliability, adhesion reliability, and visibility of the openings OP.

The cover layer SCV may be disposed under the support layer PLT. The cover layer SCV may be coupled to the support layer PLT by an adhesive member. The cover layer SCV may cover the openings OP formed in the support layer PLT. Accordingly, the cover layer SCV may prevent infiltration (or permeation) of foreign matter into the openings OP. The cover layer SCV may have a lower elastic modulus than the support layer PLT. For example, the cover layer SCV may include thermoplastic poly-urethane, rubber, or silicone, but embodiments are not limited thereto.

The digitizer DGZ may be disposed under the support layer PLT. The digitizer DGZ may be attached to the support layer PLT by a sixth adhesive layer AL6. Digitizers DGZ may be provided. For example, the digitizers DGZ may be spaced apart from each other in the second direction DR2. A portion of each of the digitizers DGZ may overlap the non-folding region NFA1 or NFA2, and the remaining portion may overlap the folding region FA. In plan view, a portion of each of the digitizers DGZ may overlap some of the openings OP.

Each of the digitizers DGZ may include loop coils that generate a magnetic field at a certain resonant frequency with an input device (hereinafter, referred to as a pen). The digitizers DGZ may be referred to as an electromagnetic field radiation (EMR) detection panel.

The magnetic field formed by the digitizers DGZ may be applied to an LC resonance circuit of the pen that includes an inductor (e.g., a coil) and a capacitor. The coil may generate a current by the received magnetic field and may transfer the generated current to the capacitor. The capacitor may change the current input from the coil and discharges the charged current to the coil. Accordingly, a magnetic field of a resonant frequency is emitted to the coil. The magnetic field emitted by the pen may be absorbed by the loop coils of the digitizers DGZ again, and thus the position of the pen adjacent to the digitizers DGZ may be determined.

Shielding layers MMP may be provided. The shielding layers MMP may be disposed under the digitizers DGZ. The shielding layers MMP may include magnetic metal powder. The shielding layers MMP may be referred to as a magnetic metal powder layer, a magnetic layer, a magnetic circuit layer, or a magnetic path layer. The shielding layers MMP may shield a magnetic field.

Heat radiating layers CU may be provided. The heat radiating layers CU may be disposed under the shielding layers MMP, respectively. The heat radiating layers CU may be sheets having high thermal conductivity. For example, the heat radiating layers CU may include graphite, copper, or a copper alloy, but embodiments are not limited thereto.

Protective layers PET may be provided. The protective layers PET may be disposed under the heat radiating layers CU, respectively. The protective layers PET may be insulating layers. For example, the protective layers PET may be layers provided to prevent introduction of static electricity. Accordingly, the protective layers PET may prevent the flexible circuit film FCB (refer to FIG. 2A) from electrically interfering with members disposed on the protective layers PET.

Waterproof tapes WFT may be provided. The waterproof tapes WFT may be attached to the shielding layers MMP and the protective layers PET. The waterproof tapes WFT may be attached to a set bracket. The thickness of waterproof tapes attached to the shielding layers MMP and the thickness of waterproof tapes attached to the protective layers PET among the waterproof tapes WFT may differ from each other.

A through-hole COP may be formed in at least some components of the lower member LM. The through-hole COP may overlap (or correspond to) the sensor region ED-SA (refer to FIG. 1A) of the electronic device EDE. At least a portion of the camera module CMM (refer to FIG. 2A) may be inserted into the through-hole COP.

In FIG. 3, the through-hole COP is illustrated as being provided from a rear surface of a protective layer among the protective layers PET to the fifth adhesive layer AL5. However, embodiments are not limited thereto. For example, the through-hole COP may be provided from the rear surface of the protective layer to an upper surface of the panel protection layer PPF or from the rear surface of the protective layer to an upper surface of the fourth adhesive layer AL4.

FIG. 4 is a schematic plan view of the display panel DP according to an embodiment.

Referring to FIG. 4, the display region DP-DA and the non-display region DP-NDA around the display region DP-DA may be defined in the display panel DP. The display region DP-DA and the non-display region DP-NDA may be distinguished from each other according to whether pixels PX are disposed. The pixels PX are disposed in the display region DP-DA. A scan driver SDV, a data driver, and an emission driver EDV may be disposed in the non-display region DP-NDA. The data driver may be a circuit configured in the driver IC DIC.

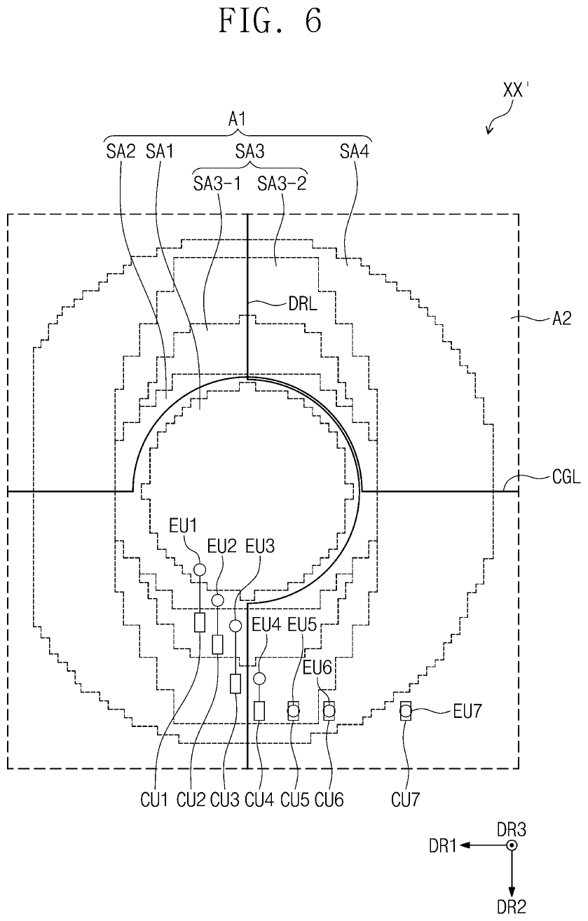

The display region DP-DA may include the first region A1 and the second region A2. The first region A1 and the second region A2 may be distinguished from each other according to the gaps between the pixels PX, the sizes of the pixels PX, the shapes of the pixels PX, or the presence or absence of a transmissive region TP (refer to FIG. 6). Detailed descriptions about the first region A1 and the second region A2 will be given below.

The display panel DP may include a first panel region AA1, a bending region BA, and a second panel region AA2 that are defined in the second direction DR2. The second panel region AA2 and the bending region BA may be partial regions of the non-display region DP-NDA. The bending region BA may be disposed between the first panel region AA1 and the second panel region AA2.

The first panel region AA1 may be a region corresponding to the display surface DS of FIG. 1A. The first panel region AA1 may include a first non-folding region NFA10, a second non-folding region NFA20, and a folding region FAO. The first non-folding region NFA10, the second non-folding region NFA20, and the folding region FAO correspond to the first non-folding region NFA1, the second non-folding region NFA2, and the folding region FA of FIGS. 1A and 1B, respectively.

The width of the bending region BA and the width (or, length) of the second panel region AA2 that are parallel to the first direction DR1 may be smaller than the width (or, length) of the first panel region AA1 that is parallel to the first direction DR1. A region having a smaller length in the direction of a bending axis may be more readily bent.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PL, and pads PD. Here, “m” and “n” are natural numbers of 2 or larger.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driver SDV. The data lines DL1 to DLn may extend in the second direction DR2 and may be electrically connected to the driver IC DIC via the bending region BA. The emission control lines ECL1 to ECLm may extend in a direction opposite to the first direction DR1 and may be electrically connected to the emission driver EDV.

The drive voltage line PL may include a portion extending in the first direction DR1 and a portion extending in the second direction DR2. The portion extending in the first direction DR1 and the portion extending in the second direction DR2 may be disposed on different layers. The portion of the drive voltage line PL that extends in the second direction DR2 may extend to the second panel region AA2 via the bending region BA. The drive voltage line PL may provide a drive voltage to the pixels PX.

The first control line CSL1 may be connected to the scan driver SDV and may extend toward a lower end of the second panel region AA2 via the bending region BA. The second control line CSL2 may be connected to the emission driver EDV and may extend toward the lower end of the second panel region AA2 via the bending region BA.

The pads PD may be disposed adjacent to the lower end of the second panel region AA2 in plan view. The driver IC DIC, the drive voltage line PL, the first control line CSL1, and the second control line CSL2 may be electrically connected to the pads PD. The flexible circuit film FCB may be electrically connected to the pads PD through an anisotropic conductive adhesive layer.

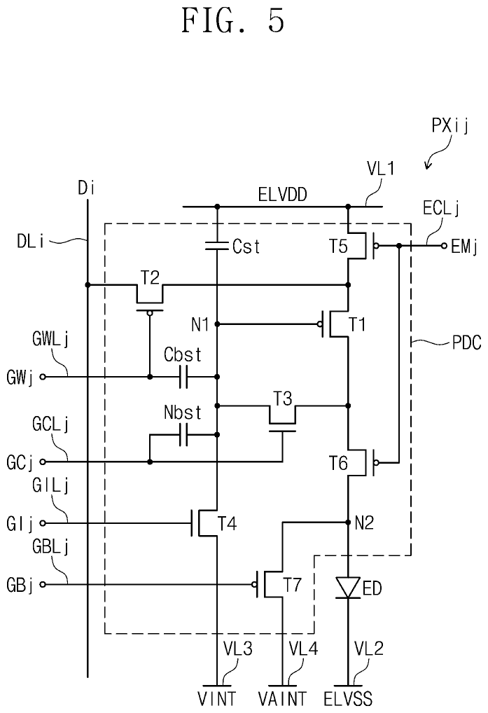

FIG. 5 is an equivalent circuit diagram of a pixel PXij according to an embodiment.

FIG. 5 illustrates the equivalent circuit diagram of the pixel PXij among the pixels PX (refer to FIG. 4). Each of the pixels PX may have the same circuit structure. Therefore, description of the circuit structure for the pixel PXij may be applied to the remaining pixels PX, and detailed description of the remaining pixels PX will be omitted.

Referring to FIGS. 4 and 5, the pixel PXij may be connected to the i^{th} data line DLi among the data lines DL1 to DLn, the j^{th} initialization scan line GILj among the initialization scan lines GILL to GILm, the j^{th} compensation scan line GCLj among the compensation scan lines GCL1 to GCLm, the j^{th} write scan line GWLj among the write scan lines GWL1 to GWLm, the j^{th} black scan line GBLj among the black scan lines GBL1 to GBLm, the j^{th} emission control line ECLj among the emission control lines ECL1 to ECLm, first and second drive voltage lines VL1 and VL2, and first and second initialization voltage lines VL3 and VL4. “i” is an integer of 1 to n, and “j” is an integer of 1 to m.

The pixel PXij may include a light emitting element ED and a pixel circuit PDC. The light emitting element ED may be a light emitting diode. In an embodiment, the light emitting element ED may be an organic light emitting diode including an organic light emitting layer, but embodiments are not limited thereto. The pixel circuit PDC may control the amount of current flowing through the light emitting element ED in response to an data signal Di. The light emitting element ED may emit light having a certain luminance in response to the amount of current provided from the pixel circuit PDC.

The pixel circuit PDC may include first to seventh transistors T1, T2, T3, T4, T5, T6, and T7 and first to third capacitors Cst, Cbst, and Nbst. A configuration of the pixel circuit PDC according to embodiments are not limited to the embodiment illustrated in FIG. 5. The pixel circuit PDC illustrated in FIG. 5 is merely an example, and various changes and modifications can be made to the configuration of the pixel circuit PDC.

At least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

Specifically, the first transistor T1 directly affecting the brightness of the light emitting element ED may include a semiconductor layer formed of polycrystalline silicon having high reliability, and thus the display device DD having a high resolution may be implemented. For example, an oxide semiconductor may have high carrier mobility and low leakage current, and therefore a voltage drop may not be great even though operating time is long. For example, the color of an image may not be greatly changed according to a voltage drop even during a low-frequency operation, and therefore the low-frequency operation is possible. Since the oxide semiconductor has an advantage of low leakage current as described above, at least one of the third transistor T3, which is connected to a gate electrode of the first transistor T1, and the fourth transistor T4 may be implemented as an oxide semiconductor to reduce power consumption with preventing leakage current that is likely to flow to the gate electrode.

Some of the first to seventh transistors T1, T2, T3, T4, T5, T6, and T7 may be P-type transistors, and the others may be N-type transistors. For example, the first, second, fifth, sixth, and seventh transistors T1, T2, T5, T6, and T7 may be P-type transistors, and the third and fourth transistors T3 and T4 may be N-type transistors.

A configuration of the pixel circuit PDC is not limited to the embodiment illustrated in FIG. 5. The pixel circuit PDC illustrated in FIG. 5 is an example, and various changes and modifications can be made to the configuration of the pixel circuit PDC. For example, the first to seventh transistors T1, T2, T3, T4, T5, T6, and T7 may all be P-type transistors or N-type transistors. In another example, the first, second, fifth, and sixth transistors T1, T2, T5, and T6 may be P-type transistors, and the third, fourth, and seventh transistors T3, T4, and T7 may be N-type transistors.

The j^{th} initialization scan line GILj, the j^{th} compensation scan line GCLj, the j^{th} write scan line GWLj, the j^{th} black scan line GBLj, and the j^{th} emission control line ECLj may transfer the j^{th} initialization scan signal GIj, the j^{th} compensation scan signal GCj, the j^{th} write scan signal GWj, the j^{th} black scan signal GBj, and the j^{th} emission control signal EMj to the pixel PXji, respectively. The i^{th} data line DLi may transfer the i^{th} data signal Di to the pixel PXij. The i^{th} data signal Di may have a voltage level corresponding to an image signal that is input to the display device DD (refer to FIG. 3).

The first and second drive voltage lines VL1 and VL2 may transfer a first drive voltage ELVDD and a second drive voltage ELVSS to the pixel PXij, respectively. Furthermore, the first and second initialization voltage lines VL3 and VL4 may transfer a first initialization voltage VINT and a second initialization voltage VAINT to the pixel PXij, respectively.

The first transistor T1 may be connected between the first drive voltage line VL1 receiving the first drive voltage ELVDD and the light emitting element ED. The first transistor T1 may include a first electrode connected to the first drive voltage line VL1 via the fifth transistor T5, a second electrode connected to a pixel electrode (or, referred to as an anode) of the light emitting element ED via the sixth transistor T6, and a third electrode (e.g., a gate electrode) connected to an end portion of the first capacitor Cst (e.g., a first node N1). The first transistor T1 may receive the i^{th} data signal Di transferred through the i^{th} data line DLi according to a switching operation of the second transistor T2 and may supply a drive current to the light emitting element ED.

The second transistor T2 may be connected between the i^{th} data line DLi and the first electrode of the first transistor T1. The second transistor T2 may include a first electrode connected to the i^{th} data line DLi, a second electrode connected to the first electrode of the first transistor T1, and a third electrode (e.g., a gate electrode) connected to the j^{th} write scan line GWLj. The second transistor T2 may be turned on in response to the j^{th} write scan signal GWj transferred through the j^{th} write scan line GWLj and may transfer, to the first electrode of the first transistor T1, the i^{th} data signal Di transferred from the i^{th} data line DLi. An end portion of the second capacitor Cbst may be connected to the third electrode of the second transistor T2, and an opposite end of the second capacitor Cbst may be connected to the first node N1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the j^{th} compensation scan line GCLj. The third transistor T3 may be turned on in response to the j^{th} compensation scan signal GCj transferred through the i^{th} compensation scan line GCLj and may diode-connect the first transistor T1 by connecting the third electrode and the second electrode of the first transistor T1. An end portion of the third capacitor Nbst may be connected to the third electrode of the third transistor T3, and an opposite end of the third capacitor Nbst may be connected to the first node N1.

The fourth transistor T4 may be connected between the first initialization voltage line VL3, through which the first initialization voltage VINT is applied, and the first node N1. The fourth transistor T4 may include a first electrode connected to the first initialization voltage line VL3, through which the first initialization voltage VINT is transferred, a second electrode connected to the first node N1, and a third electrode (e.g., a gate electrode) connected to the i^{th} initialization scan line GILj. The fourth transistor T4 may be turned on in response to the j^{th} initialization scan signal GIj transferred through the j^{th} initialization scan line GILj. The turned-on fourth transistor T4 may initialize the potential of the third electrode of the first transistor T1 (e.g., the potential of the first node N1) by transferring the first initialization voltage VINT to the first node N1.

The fifth transistor T5 may include a first electrode connected to the first drive voltage line VL1, a second electrode connected to the first electrode of the first transistor T1, and a third electrode (e.g., a gate electrode) connected to the j^{th} emission control line ECLj. The sixth transistor T6 may include a first electrode connected to the second electrode of the first transistor T1, a second electrode connected to the pixel electrode of the light emitting element ED, and a third electrode (e.g., a gate electrode) connected to the j^{th} emission control line ECLj.

The fifth and sixth transistors T5 and T6 may be simultaneously turned on in response to the j^{th} emission control signal EMj transferred through the j^{th} emission control line ECLj. The first drive voltage ELVDD applied through the turned-on fifth transistor T5 may be compensated for through the diode-connected first transistor T1 and thereafter may be transferred to the light emitting element ED through the sixth transistor T6.

The seventh transistor T7 may include a first electrode connected to the second initialization voltage line VL4 through which the second initialization voltage VAINT is transferred, a second electrode connected to the second electrode of the sixth transistor T6, and a third electrode (e.g., a gate electrode) connected to the j^{th} black scan line GBLj. The second initialization voltage VAINT may have a voltage level lower than or equal to the voltage level of the first initialization voltage VINT.

The end portion of the first capacitor Cst may be connected to the third electrode of the first transistor T1, and an opposite end of the first capacitor Cst may be connected to the first drive voltage line VL1. A cathode of the light emitting element ED may be connected to the second drive voltage line VL2 that transfers the second drive voltage ELVSS. The second drive voltage ELVSS may have a lower voltage level than the first drive voltage ELVDD.

FIG. 6 is a schematic enlarged plan view illustrating a partial region of the display panel according to an embodiment. FIG. 6 is a schematic enlarged plan view illustrating region XX′ illustrated in FIG. 4.

Referring to FIGS. 4 and 6, the display panel DP may include the first region A1 and the second region A2. First to sixth type light emitting units EU1, EU2, EU3, EU4, EU5, and EU6 may be disposed in the first region A1, and a seventh type light emitting unit EU7 may be disposed in the second region A2.

An arrangement or operation of light emitting elements included in the first to sixth type light emitting units EU1, EU2, EU3, EU4, EU5, and EU6 may differ from that of the seventh type light emitting unit EU7. For example, each of the first to sixth type light emitting units EU1, EU2, EU3, EU4, EU5, and EU6 may include light emitting elements operated by the pixel circuit PDC (refer to FIG. 5), and light emitting elements included in the seventh type light emitting unit EU7 may be operated by the pixel circuit PDC (refer to FIG. 5). Specific description thereabout will be given below.

The first region A1 may include a first sub-region SA1, a second sub-region SA2, a plurality of third sub-regions SA3, and a fourth sub-region SA4. The second sub-region SA2 may surround the first sub-region SAL The third sub-regions SA3 may be spaced apart from each other with the second sub-region SA2 therebetween, e.g., in the second direction DR2. The fourth sub-region SA4 may surround the second sub-region SA2 and the third sub-regions SA3. The second region A2 may surround the first region A1.

The first sub-region SA1 may have a higher transmittance than the second to fourth sub-regions SA2, SA3, and SA4 and the second region A2.

The first type light emitting unit EU1 may be disposed in the first sub-region SA1, and a first pixel circuit unit CU1 that controls an operation of the first type light emitting unit EU1 may be disposed in one of the third sub-regions SA3. The second type light emitting unit EU2 may be disposed in the second sub-region SA2, and a second pixel circuit unit CU2 that controls an operation of the second type light emitting unit EU2 may be disposed in one of the third sub-regions SA3. The one of the third sub-regions SA3 may be a third sub-region SA3 close to each of the first type light emitting unit EU1 and the second type light emitting unit EU2.

The first sub-region SA1 may be a region through which light to be provided to the camera module CMM (refer to FIG. 2A) passes. Since the first pixel circuit unit CU1 is not disposed in the first sub-region SA1, the transmittance (or light transmittance) of the first sub-region SA1 may be further improved. Accordingly, the quality of an image obtained by the camera module CMM (refer to FIG. 2A) may be improved.

The second sub-region SA2 may be a region through which lines CGL and DRL bypass the first sub-region SA1 without intersecting the first sub-region SAL The line CGL having a portion extending in the first direction DR1 may be a part of each of the initialization scan lines GIL1 to GILm, the compensation scan lines GCL1 to GCLm, the write scan lines GWL1 to GWLm, the black scan lines GBL1 to GBLm, and the emission control lines ECL1 to ECLm described with reference to FIG. 4. The line DRL having a portion extending in the second direction DR2 may be a part of the data lines DL1 to DLn described with reference to FIG. 4. Although a single line CGL and a single line DRL are illustrated in FIG. 6, lines CGL and lines DRL may be provided.

According to an embodiment, the transmittance of the first sub-region SA1 may be further improved since the lines CGL and DRL bypass the first sub-region SA1 through the second sub-region SA2 without intersecting the first sub-region SAL Accordingly, the quality of an image obtained by the camera module CMM (refer to FIG. 2A) may be improved.

Each of the third sub-regions SA3 may include a (3-1)th sub-region SA3-1 and a (3-2)th sub-region SA3-2. For example, the first pixel circuit unit CU1 and the second pixel circuit unit CU2 may be disposed in the (3-1)th sub-region SA3-1. Therefore, a space in which a third pixel circuit unit CU3 that controls an operation of the third type light emitting unit EU3 is to be disposed may be insufficient. Accordingly, the third type light emitting unit EU3 may be disposed in the (3-1)th sub-region SA3-1, and the third pixel circuit unit CU3 may be disposed in the (3-2)th sub-region SA3-2.

The fourth type light emitting unit EU4 and the fifth type light emitting unit EU5 may be disposed in the (3-2)th sub-region SA3-2. The fourth type light emitting unit EU4 may be spaced apart from a fourth pixel circuit unit CU4 that controls an operation of the fourth type light emitting unit EU4, and the fifth type light emitting unit EU5 may overlap a fifth pixel circuit unit CU5 that controls an operation of the fifth type light emitting unit EU5.

The sixth type light emitting unit EU6 may be disposed in the fourth sub-region SA4. The sixth type light emitting unit EU6 may overlap a sixth pixel circuit unit CU6 that controls an operation of the sixth type light emitting unit EU6. In another example, the fourth sub-region SA4 may be omitted. For example, the second region A2 may be expanded to surround the second sub-region SA2 and the third sub-regions SA3.

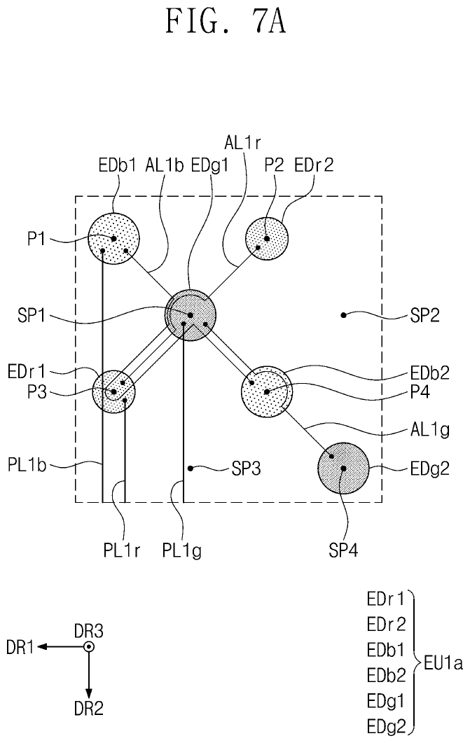

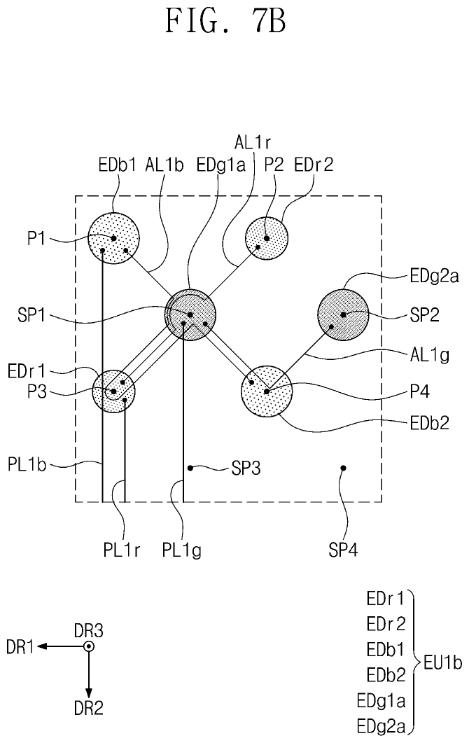

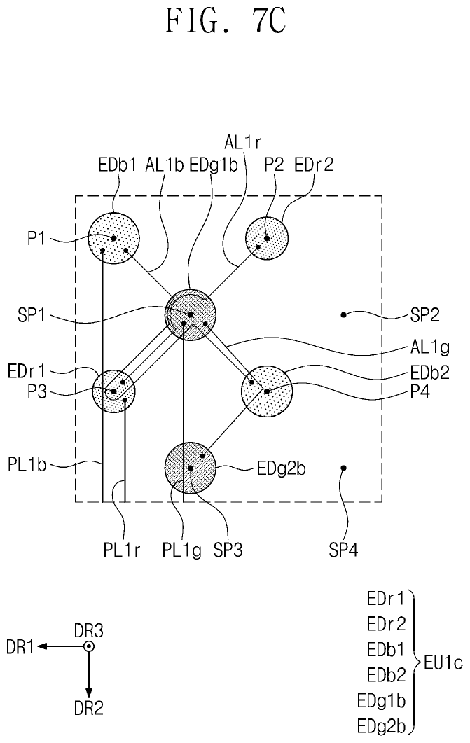

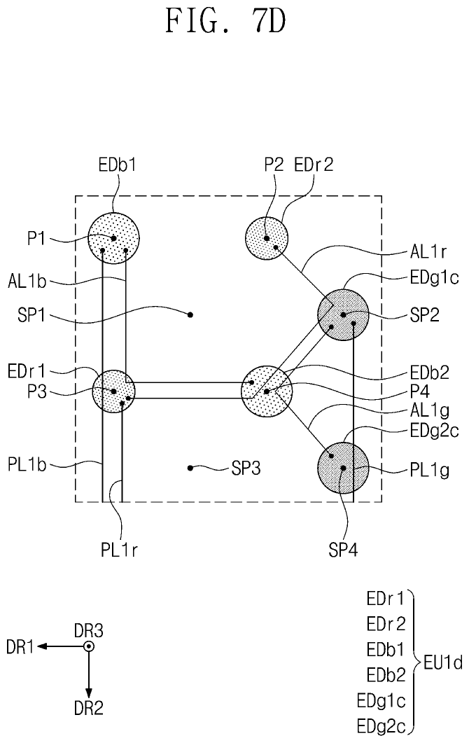

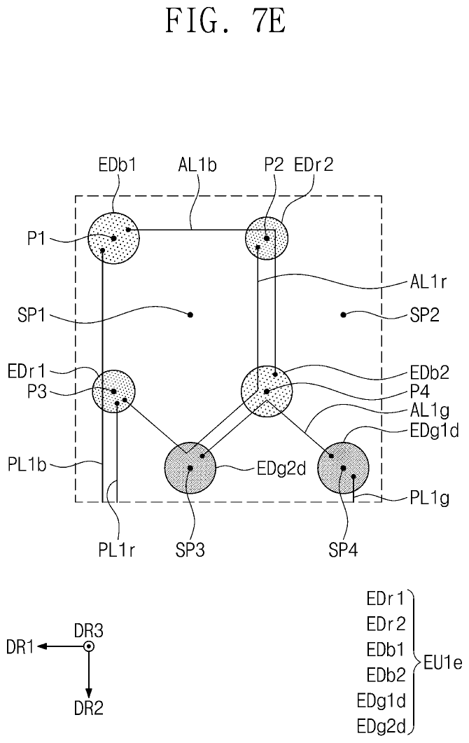

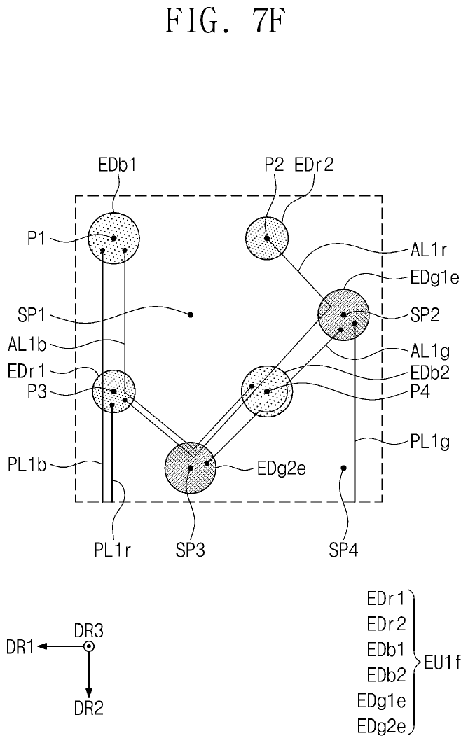

FIGS. 7A to 7F are schematic plan views illustrating light emitting units according to embodiments. First to sixth light emitting units EU1a, EU1b, EU1c, EU1d, EU1e, and EU1f illustrated in FIGS. 7A to 7F are examples of the first type light emitting unit EU1 (refer to FIG. 6).

Referring to FIGS. 6 and 7A to 7F, first type light emitting units EU1 may be provided. For example, the first type light emitting units EU1 may be disposed in the first sub-region SAL The first type light emitting units EU1 may include at least two light emitting units having different arrangement rules (or patterns). The at least two light emitting units may include a light emitting unit and another light emitting unit that are selected from the group including the first to sixth light emitting units EU1a, EU1b, EU1c, EU1d, EU1e, and EU1f illustrated in FIGS. 7A to 7F.

According to a comparative example, arrangement rules (or patterns) of light emitting elements included in the first type light emitting units EU1 may all be the same. For example, a light blurring phenomenon (or light flare phenomenon) and a double image (e.g., ghost) may occur due to the regular arrangements of the light emitting elements. According to an embodiment, light emitting elements disposed in the first sub-region SA1 may be implemented in a random arrangement structure that is able to be designed and manufactured since the first type light emitting units EU1 include at least two light emitting units having different arrangement rules (or patterns). Accordingly, the light blurring phenomenon due to the regular arrangements of the light emitting elements may be alleviated or eliminated. Also, the double image may be eliminated, the spacing of the double image may be decreased, or the unnecessary clarity of the double image may be reduced. Thus, the quality of an image obtained by the camera module CMM (refer to FIG. 2A) may be improved or enhanced.

First to fourth points P1, P2, P3, and P4 and first to fourth selection points SP1, SP2, SP3, and SP4 may be defined in each of the first to sixth light emitting units EU1a, EU1b, EU1c, EU1d, EU1e, and EU1f. The first point P1 and the second point P2 may be spaced apart from each other in the first direction DR1, the first point P1 and the third point P3 may be spaced apart from each other in the second direction DR2, and the third point P3 and the fourth point P4 may be spaced apart from each other in the first direction DR1. The first selection point SP1 may be defined between the first to fourth points P1, P2, P3, and P4. The first selection point SP1 and the second selection point SP2 may be spaced apart from each other in the first direction DR1, the first selection point SP1 and the third selection point SP3 may be spaced apart from each other in the second direction DR2, and the third selection point SP3 and the fourth selection point SP4 may be spaced apart from each other in the first direction DR1.

Referring to FIG. 7A, the first light emitting unit EU1a may include six first arrangement light emitting elements EDr1, EDr2, EDg1, EDg2, EDb1, and EDb2. The first arrangement light emitting elements EDr1, EDr2, EDg1, EDg2, EDb1, and EDb2 may include the (1-1)th light emitting elements EDr1 and EDr2, the (1-2)th light emitting elements EDg1 and EDg2, and the (1-3)th light emitting elements EDb1 and EDb2.

Referring to FIG. 7B, the second light emitting unit EU1b may include six second arrangement light emitting elements EDr1, EDr2, EDg1a, EDg2a, EDb1, and EDb2. The second arrangement light emitting elements EDr1, EDr2, EDg1a, EDg2a, EDb1, and EDb2 may include the (2-1)th light emitting elements EDr1 and EDr2, the (2-2)th light emitting elements EDg1a and EDg2a, and the (2-3)th light emitting elements EDb1 and EDb2.

Referring to FIG. 7C, the third light emitting unit EU1c may include (3-1)th light emitting elements EDr1 and EDr2, (3-2)th light emitting elements EDg1b and EDg2b, and (3-3)th light emitting elements EDb1 and EDb2.

Referring to FIG. 7D, the fourth light emitting unit EU1d may include (4-1)th light emitting elements EDr1 and EDr2, (4-2)th light emitting elements EDg1c and EDg2c, and (4-3)th light emitting elements EDb1 and EDb2.

Referring to FIG. 7E, the fifth light emitting unit EU1e may include (5-1)th light emitting elements EDr1 and EDr2, (5-2)th light emitting elements EDg1d and EDg2d, and (5-3)th light emitting elements EDb1 and EDb2.

Referring to FIG. 7F, the sixth light emitting unit EU1f may include (6-1)th light emitting elements EDr1 and EDr2, (6-2)th light emitting elements EDg1e and EDg2e, and (6-3)th light emitting elements EDb1 and EDb2.

The (1-1)th light emitting elements EDr1 and EDr2, the (2-1)th light emitting elements EDr1 and EDr2, the (3-1)th light emitting elements EDr1 and EDr2, the (4-1)th light emitting elements EDr1 and EDr2, the (5-1)th light emitting elements EDr1 and EDr2, and the (6-1)th light emitting elements EDr1 and EDr2 may have the same arrangement rule (or pattern) and are assigned with the same reference numerals in FIGS. 7A and 7F. The (1-3)th light emitting elements EDb1 and EDb2, the (2-3)th light emitting elements EDb1 and EDb2, the (3-3)th light emitting elements EDb1 and EDb2, the (4-3)th light emitting elements EDb1 and EDb2, the (5-3)th light emitting elements EDb1 and EDb2, and the (6-3)th light emitting elements EDbr1 and EDb2 may have the same arrangement rule (or pattern) and are assigned with the same reference numerals in FIGS. 7A and 7F. Hereinafter, the (1-1)th light emitting elements EDr1 and EDr2 and the (1-3)th light emitting elements EDb1 and EDb2 will be representatively described. The contents described below may be identically applied to the remaining light emitting elements that share the same reference numerals.

The (1-1)th light emitting elements EDr1 and EDr2 may be disposed at the second point P2 and the third point P3, respectively. The (1-1)th light emitting elements EDr1 and EDr2 may be electrically connected to each other by a first connecting line AL1r. A first circuit connecting line PL1r may be connected to one of the (1-1)th light emitting elements EDr1 and EDr2. Although FIG. 7A illustrates an example that the first circuit connecting line PL1r is connected to the (1-1)th light emitting element EDr1, embodiments are not limited thereto. For example, the first circuit connecting line PL1r may be connected to the (1-1)th light emitting element EDr2. Operations of the (1-1)th light emitting elements EDr1 and EDr2 may be controlled by a single pixel circuit. Accordingly, the (1-1)th light emitting elements EDr1 and EDr2 may have a two-copy structure.

The (1-2)th light emitting elements EDg1 and EDg2, the (2-2)th light emitting elements EDg1a and EDg2a, the (3-2)th light emitting elements EDg1b and EDg2b, the (4-2)th light emitting elements EDg1c and EDg2c, the (5-2)th light emitting elements EDg1d and EDg2d, and the (6-2)th light emitting elements EDg1e and EDg2e may have different arrangement rules (or pattern). The arrangement rules (or patterns) of the (1-2)th light emitting elements EDg1 and EDg2, the (2-2)th light emitting elements EDg1a and EDg2a, the (3-2)th light emitting elements EDg1b and EDg2b, the (4-2)th light emitting elements EDg1c and EDg2c, the (5-2)th light emitting elements EDg1d and EDg2d, and the (6-2)th light emitting elements EDg1e and EDg2e may correspond to six combinations implemented with the first to fourth selection points SP1, SP2, SP3, and SP4.

The (1-2)th light emitting elements EDg1 and EDg2 may be disposed at the first selection point SP1 and the fourth selection point SP4, respectively. The (2-2)th light emitting elements EDg1a and EDg2a may be disposed at the first selection point SP1 and the second selection point SP2, respectively. The (3-2)th light emitting elements EDg1b and EDg2b may be disposed at the first selection point SP1 and the third selection point SP3, respectively. The (4-2)th light emitting elements EDg1c and EDg2c may be disposed at the second selection point SP2 and the fourth selection point SP4, respectively. The (5-2)th light emitting elements EDg1d and EDg2d may be disposed at the third selection point SP3 and the fourth selection point SP4, respectively. The (6-2)th light emitting elements EDg1e and EDg2e may be disposed at the second selection point SP2 and the third selection point SP3, respectively.

The (1-2)th light emitting elements EDg1 and EDg2 may be electrically connected to each other by a second connecting line AL1g. A second circuit connecting line PL1g may be connected to one of the (1-2)th light emitting elements EDg1 and EDg2. Although FIG. 7A illustrates an example that the second circuit connecting line PL1g is connected to the (1-2)th light emitting element EDg1, embodiments are not limited thereto. Operations of the (1-2)th light emitting elements EDg1 and EDg2 may be controlled by a single pixel circuit. Accordingly, the (1-2)th light emitting elements EDg1 and EDg2 may have a two-copy structure.

The (1-3)th light emitting elements EDb1 and EDb2 may be disposed at the first point P1 and the fourth point P4, respectively. The (1-3)th light emitting elements EDb1 and EDb2 may be electrically connected to each other by a third connecting line AL1b. A third circuit connecting line PL1b may be connected to one of the (1-3)th light emitting elements EDb1 and EDb2. Although FIG. 7A illustrates an example that the third circuit connecting line PL1b is connected to the (1-3)th light emitting element EDb1, embodiments are not limited thereto. For example, the third circuit connecting line PL1b may be connected to the (1-3)th light emitting element EDb2. Operations of the (1-3)th light emitting elements EDb1 and EDb2 may be controlled by a single pixel circuit. Accordingly, the (1-3)th light emitting elements EDb1 and EDb2 may have a two-copy structure.

The (1-1)th, (2-1)th, (3-1)th, (4-1)th, (5-1)th, and (6-1)th light emitting elements EDr1 and EDr2 may be red light emitting elements, the (1-3)th, (2-3)th, (3-3)th, (4-3)th, (5-3)th, and (6-3)th light emitting elements EDb1 and EDb2 may be blue light emitting elements, and the (1-2)th light emitting elements EDg1 and EDg2, the (2-2)th light emitting elements EDg1a and EDg2a, the (3-2)th light emitting elements EDg1b and EDg2b, the (4-2)th light emitting elements EDg1c and EDg2c, the (5-2)th light emitting elements EDg1d and EDg2d, and the (6-2)th light emitting elements EDg1e and EDg2e may be green light emitting elements. Accordingly, the red light emitting elements of the light emitting units may have the same arrangement rule (or pattern), the blue light emitting elements of the light emitting units may have the same arrangement rule (or pattern), and the green light emitting elements of the light emitting units may have different arrangement rules (or patterns).

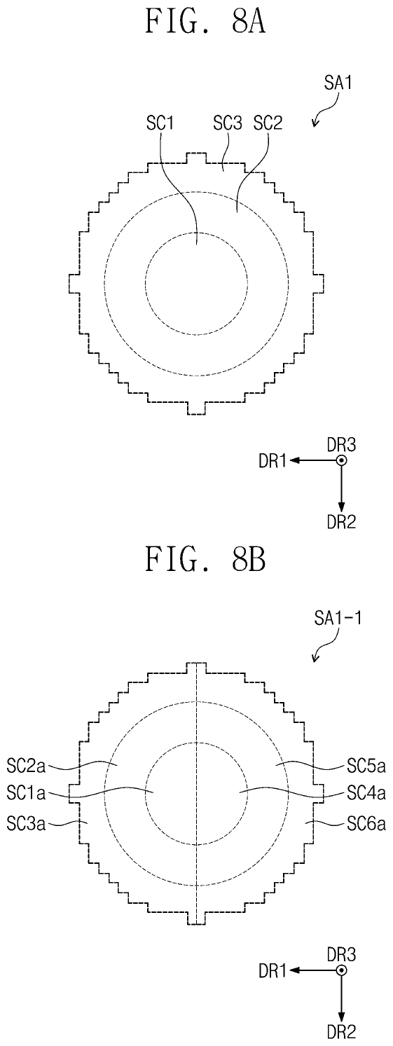

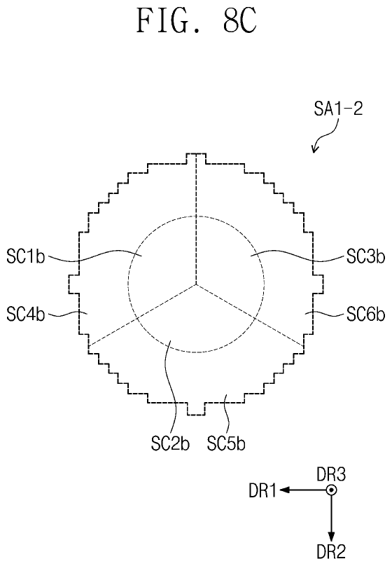

FIG. 8A is a schematic plan view illustrating the first sub-region SA1 according to an embodiment.

Referring to FIG. 8A, the first sub-region SA1 may include first to third zones SC1, SC2, and SC3. The first to third zones SC1, SC2, and SC3 may be divided from each other by concentric circles. The first zone SC1 may be disposed at the center portion, the second zone SC2 may surround the first zone SC1, and the third zone SC3 may surround the second zone SC2.

Three different light emitting units selected from the group including the first to sixth light emitting units EU1a, EU1b, EU1c, EU1d, EU1e, and EU1f illustrated in FIGS. 7A to 7F may be disposed in the first to third zones SC1, SC2, and SC3, respectively. For example, the first light emitting unit EU1a may be disposed in the first zone SC1, the third light emitting unit EU1c may be disposed in the second zone SC2, and the sixth light emitting unit EU1f may be disposed in the third zone SC3. However, this is an example, and various combinations of the light emitting units may be disposed in the zones.

According to an embodiment, since the three different light emitting units are disposed in the direction away from the center portion of the first sub-region SA1, it may be more advantageous to alleviate or eliminate a radial light blurring phenomenon. Accordingly, the quality of an image obtained by the camera module CMM (refer to FIG. 2A) may be improved.

Although FIG. 8A illustrates an example that the first sub-region SA1 is divided into the three zones, embodiments are not limited thereto. For example, the first sub-region SA1 may include two zones divided from each other by one circle, or may include four or more zones divided from each other by three or more concentric circles.

FIG. 8B is a schematic plan view illustrating a first sub-region SA1-1 according to an embodiment.

Referring to FIG. 8b, the first sub-region SA1-1 may include first to sixth zones SC1a, SC2a, SC3a, SC4a, SC5a, and SC6a. The first to sixth zones SC1a, SC2a, SC3a, SC4a, SC5a, and SC6a may be divided from each other by concentric circles and a line that extends in a certain direction.

Six different light emitting units selected from the group including the first to sixth light emitting units EU1a, EU1b, EU1c, EU1d, EU1e, and EU1f illustrated in FIGS. 7A to 7F may be disposed in the first to sixth zones SC1a, SC2a, SC3a, SC4a, SC5a, and SC6a, respectively. Since the six different light emitting units are all disposed in the first sub-region SA1-1, light emitting elements in the first sub-region SA1-1 may be disposed in a more random arrangement structure. Accordingly, the degree of improvement in a light blurring phenomenon and a double image phenomenon may be further improved. Thus, the quality of an image obtained by the camera module CMM (refer to FIG. 2A) may be improved.

FIG. 8C is a schematic plan view illustrating a first sub-region SA1-2 according to an embodiment.

Referring to FIG. 8C, the first sub-region SA1-2 may include first to sixth zones SC1b, SC2b, SC3b, SC4b, SC5b, and SC6b. The first to sixth zones SC1b, SC2b, SC3b, SC4b, SC5b, and SC6b may be divided from each other by one concentric circle and three lines that extend in certain directions.

Six different light emitting units selected from the group including the first to sixth light emitting units EU1a, EU1b, EU1c, EU1d, EU1e, and EU1f illustrated in FIGS. 7A to 7F may be disposed in the first to sixth zones SC1b, SC2b, SC3b, SC4b, SC5b, and SC6b, respectively. Since the six different light emitting units are all disposed in the first sub-region SA1-2, light emitting elements in the first sub-region SA1-2 may be disposed in a more random arrangement structure. Accordingly, the degree of improvement in a light blurring phenomenon and a double image phenomenon may be further improved. Thus, the quality of an image obtained by the camera module CMM (refer to FIG. 2A) may be improved.

Although FIGS. 8A, 8B, and 8C illustrate examples that the first sub-region SA1, SA1-1, or SA1-2 is divided into zones, embodiments are not limited thereto. The first sub-region SA1, SA1-1, or SA1-2 may be modified in various structures as long as two or more types of light emitting units having different arrangements are able to be disposed in the first sub-region SA1, SA1-1, or SA1-2. Furthermore, in an embodiment, two or more types of light emitting units having different arrangements may be disposed in the first sub-region SA1, SA1-1, or SA1-2 without any special division of the region.

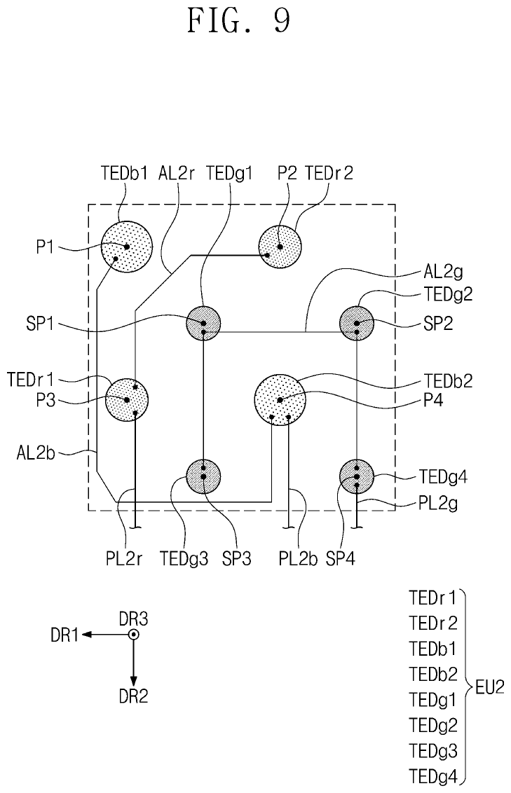

FIG. 9 is a schematic plan view illustrating a light emitting unit according to an embodiment.

Referring to FIGS. 6 and 9, the second type light emitting unit EU2 is illustrated as an example. The second type light emitting unit EU2 may be referred to as the intermediate light emitting unit.

The second type light emitting unit EU2 may include eight intermediate light emitting elements TEDr1, TEDr2, TEDb1, TEDb2, TEDg1, TEDg2, TEDg3, and TEDg4. The eight intermediate light emitting elements TEDr1, TEDr2, TEDb1, TEDb2, TEDg1, TEDg2, TEDg3, and TEDg4 may include the first color light emitting elements TEDr1 and TEDr2, the second color light emitting elements TEDg1, TEDg2, TEDg3, and TEDg4, and the third color light emitting elements TEDb1 and TEDb2. The first color light emitting elements TEDr1 and TEDr2 may be referred to as the (3-1)th light emitting elements, the second color light emitting elements TEDg1, TEDg2, TEDg3, and TEDg4 may be referred to as the (3-2)th light emitting elements, and the third color light emitting elements TEDb1 and TEDb2 may be referred to as the (3-3)th light emitting elements.

Operations of the first color light emitting elements TEDr1 and TEDr2 may be controlled by a single pixel circuit. The first color light emitting elements TEDr1 and TEDr2 may be electrically connected to each other by a first connecting line AL2r. A first circuit connecting line PL2r may be connected to one of the first color light emitting elements TEDr1 and TEDr2. Accordingly, the first color light emitting elements TEDr1 and TEDr2 may have a two-copy structure.

Operations of the second color light emitting elements TEDg1, TEDg2, TEDg3, and TEDg4 may be controlled by a single pixel circuit. The second color light emitting elements TEDg1, TEDg2, TEDg3, and TEDg4 may be electrically connected to each other by a second connecting line AL2g. A second circuit connecting line PL2g may be connected to one of the second color light emitting elements TEDg1, TEDg2, TEDg3, and TEDg4. Accordingly, the second color light emitting elements TEDg1, TEDg2, TEDg3, and TEDg4 may have a four-copy structure.

Operations of the third color light emitting elements TEDb1 and TEDb2 may be controlled by a single pixel circuit. The third color light emitting elements TEDb1 and TEDb2 may be electrically connected to each other by a third connecting line AL2b. A third circuit connecting line PL2b may be connected to one of the third color light emitting elements TEDb1 and TEDb2. Accordingly, the third color light emitting elements TEDb1 and TEDb2 may have a two-copy structure.

The number of the first color light emitting elements (e.g., the (1-1)th light emitting elements EDr1 and EDr2 (refer to FIG. 7A)) included in the first type light emitting unit EU1 and the number of the first color light emitting elements TEDr1 and TEDr2 included in the second type light emitting unit EU2 may be equal to 2 and may be the same as each other. The number of the third color light emitting elements (e.g., the (1-3)th light emitting elements EDb1 and EDb2 (refer to FIG. 7A)) included in the first type light emitting unit EU1 and the number of the third color light emitting elements TEDb1 and TEDb2 included in the second type light emitting unit EU2 may be equal to 2 and may be the same as each other. The number of the second color light emitting elements (e.g., the (1-2)th light emitting elements EDg1 and EDg2 (refer to FIG. 7A)) included in the first type light emitting unit EU1 and the number of the second color light emitting elements TEDg1, TEDg2, TEDg3, and TEDg4 included in the second type light emitting unit EU2 may be equal to 2 and 4, respectively, and may differ from each other.

The sizes of emissive regions defined in the second color light emitting elements TEDg1, TEDg2, TEDg3, and TEDg4 may be smaller than the sizes of emissive regions defined in the (1-2)th light emitting elements EDg1 and EDg2, the (2-2)th light emitting elements EDg1a and EDg2a, the (3-2)th light emitting elements EDg1b and EDg2b, the (4-2)th light emitting elements EDg1c and EDg2c, the (5-2)th light emitting elements EDg1d and EDg2d, and the (6-2)th light emitting elements EDg1e and EDg2e illustrated in FIGS. 7A to 7F.

For example, in a case in which the areas of the emissive regions of the two second color light emitting elements of the first type light emitting unit EU1 are the same as the areas of the emissive regions of the four second color light emitting elements TEDg1, TEDg2, TEDg3, and TEDg4 of the second type light emitting unit EU2, the two second color light emitting elements of the first type light emitting unit EU1 may emit brighter light than the four second color light emitting elements TEDg1, TEDg2, TEDg3, and TEDg4 of the second type light emitting unit EU2 in case that the same luminance is implemented within a reference area. However, according to an embodiment, the areas of the emissive regions of the two second color light emitting elements of the first type light emitting unit EU1 may be greater than the areas of the emissive regions of the four second color light emitting elements TEDg1, TEDg2, TEDg3, and TEDg4 of the second type light emitting unit EU2, and thus the life-spans of the two second color light emitting elements of the first type light emitting unit EU1 may be compensated for.

In an embodiment, the total area of the emissive regions defined in the two second color light emitting elements of the first type light emitting unit EU1 may be substantially the same as the total area of the emissive regions defined in the four second color light emitting elements TEDg1, TEDg2, TEDg3, and TEDg4 of the second type light emitting unit EU2.

The second sub-region SA2 may be a region through which the lines CGL and DRL bypass the first sub-region SA1 without intersecting the first sub-region SAL Accordingly, the pixel circuits for driving the second type light emitting unit EU2 may not be disposed in the second sub-region SA2.

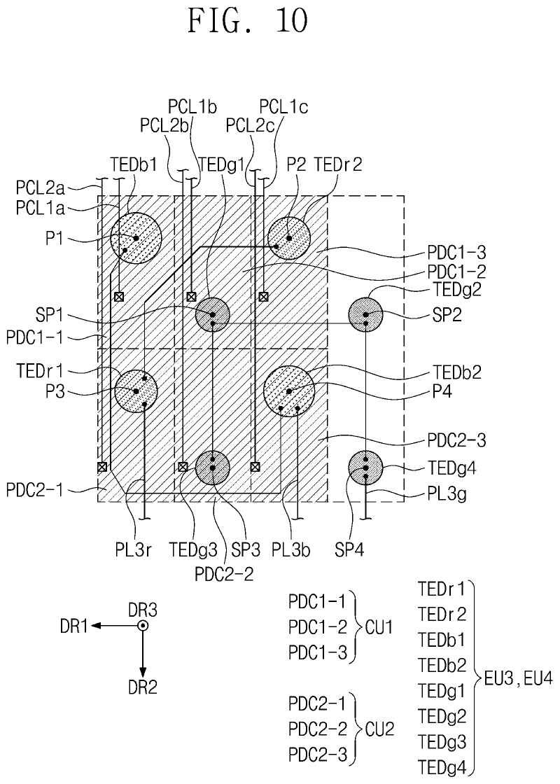

FIG. 10 is a schematic plan view illustrating a light emitting unit and pixel circuits according to an embodiment.

Referring to FIGS. 6 and 10, the third type light emitting unit EU3, the first pixel circuit unit CU1, and the second pixel circuit unit CU2 may be disposed in the (3-1)th sub-region SA3-1. The third type light emitting unit EU3 may be referred to as the intermediate light emitting unit. The third type light emitting unit EU3 may include eight intermediate light emitting elements TEDr1, TEDr2, TEDb1, TEDb2, TEDg1, TEDg2, TEDg3, and TEDg4 and may have the same arrangement as the second type light emitting unit EU2 described with reference to FIG. 9. Therefore, redundant description thereabout will be omitted for descriptive convenience.

The first pixel circuit unit CU1 may control an operation of the first type light emitting unit EU1, and the second pixel circuit unit CU2 may control an operation of the second type light emitting unit EU2.

The first pixel circuit unit CU1 may include a (1-1)th pixel circuit PDC1-1, a (1-2)th pixel circuit PDC1-2, and a (1-3)th pixel circuit PDC1-3. For example, each of the (1-1)th pixel circuit PDC1-1, the (1-2)th pixel circuit PDC1-2, and the (1-3)th pixel circuit PDC1-3 may have the same equivalent circuit as the pixel circuit PDC illustrated in FIG. 5. However, embodiments are not limited thereto.

The (1-1)th pixel circuit PDC1-1 may be connected to the first light emitting elements included in the first type light emitting unit EU1 through a first circuit connecting line PCL1a. The (1-2)th pixel circuit PDC1-2 may be connected to the second light emitting elements included in the first type light emitting unit EU1 through a second circuit connecting line PCL1b. The (1-3)th pixel circuit PDC1-3 may be connected to the third light emitting elements included in the first type light emitting unit EU1 through a third circuit connecting line PCL1c. The first to third circuit connecting lines PCL1a, PCL1b, and PCL1c may correspond to one of the first to third circuit connecting lines PL1r, PL1g, and PL1b described with reference to FIGS. 7A to 7F, another one, and the other one, respectively.

For example, the first light emitting elements may be first light emitting elements (e.g., the (1-1)th light emitting elements EDr1 and EDr2) corresponding to a single light emitting unit among the first to sixth light emitting units EU1a, EU1b, EU1c, EU1d, EU1e, and EU1f. The second light emitting elements may be second light emitting elements (e.g., the (1-2)th light emitting elements EDg1 and EDg2) corresponding to a single light emitting unit among the first to sixth light emitting units EU1a, EU1b, EU1c, EU1d, EU1e, and EU1f. The third light emitting elements may be second light emitting elements (e.g., the (1-3)th light emitting elements EDb1 and EDb2) corresponding to a single light emitting unit among the first to sixth light emitting units EU1a, EU1b, EU1c, EU1d, EU1e, and EU1f.

The second pixel circuit unit CU2 may include a (2-1)th pixel circuit PDC2-1, a (2-2)th pixel circuit PDC2-2, and a (2-3)th pixel circuit PDC2-3. For example, each of the (2-1)th pixel circuit PDC2-1, the (2-2)th pixel circuit PDC2-2, and the (2-3)th pixel circuit PDC2-3 may have the same equivalent circuit as the pixel circuit PDC illustrated in FIG. 5. However, embodiments are not limited thereto. First to third circuit connecting lines PCL2a, PCL2b, and PCL2c may correspond to one of the first to third circuit connecting lines PL2r, PL2g, and PL2b described with reference to FIG. 9, another one, and the other one, respectively.

For example, the (2-1)th pixel circuit PDC2-1 may be connected to the first color light emitting elements TEDr1 and TEDr2 included in the second type light emitting unit EU2 through the first circuit connecting line PCL2a. The (2-2)th pixel circuit PDC2-2 may be connected to the second color light emitting elements TEDg1, TEDg2, TEDg3, and TEDg4 included in the second type light emitting unit EU2 through the second circuit connecting line PCL2b. The (2-3)th pixel circuit PDC2-3 may be connected to the third color light emitting elements TEDb1 and TEDb2 included in the second type light emitting unit EU2 through the third circuit connecting line PCL2c.

Since the first pixel circuit unit CU1 and the second pixel circuit unit CU2 are disposed in the (3-1)th sub-region SA3-1, there may be no space in which the third pixel circuit unit CU3 for controlling the third type light emitting unit EU3 is to be disposed. The third type light emitting unit EU3 and the third pixel circuit unit CU3 for driving the third type light emitting unit EU3 may be spaced apart from each other without overlapping each other. The third pixel circuit unit CU3 may be disposed in the (3-2)th sub-region SA3-2.

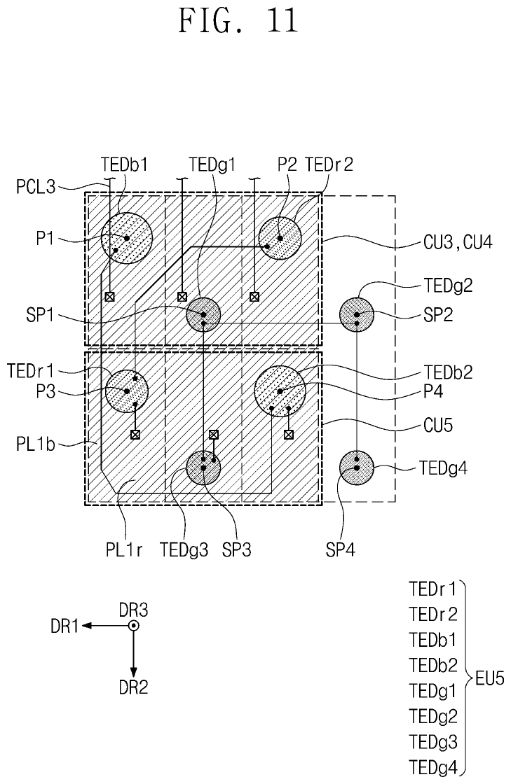

FIG. 11 is a schematic plan view illustrating a light emitting unit and pixel circuits according to an embodiment.

Referring to FIGS. 6 and 11, the fifth type light emitting unit EU5, the third pixel circuit unit CU3, and the fifth pixel circuit unit CU5 may be disposed in the (3-2)th sub-region SA3-2.

The fifth type light emitting unit EU5 may be referred to as the intermediate light emitting unit. The fifth type light emitting unit EU5 may include eight intermediate light emitting elements TEDr1, TEDr2, TEDb1, TEDb2, TEDg1, TEDg2, TEDg3, and TEDg4 and may have the same arrangement as the second type light emitting unit EU2 described with reference to FIG. 9. Therefore, redundant description thereabout will be omitted for descriptive convenience.

In FIGS. 10 and 11, a connection relationship between the third type light emitting unit EU3 and the third pixel circuit unit CU3 may be similar to a connection relationship between the fourth type light emitting unit EU4 and the fourth pixel circuit unit CU4. Therefore, the reference numerals of the third type light emitting unit EU3 and the fourth type light emitting unit EU4 indicate the same component, and the reference numerals of the third pixel circuit unit CU3 and the fourth pixel circuit unit CU4 indicate the same component. Accordingly, descriptions about the third type light emitting unit EU3 and the third pixel circuit unit CU3 may be applied to descriptions about the fourth type light emitting unit EU4 and the fourth pixel circuit unit CU4.

The third pixel circuit unit CU3 may control an operation of the third type light emitting unit EU3, the fourth pixel circuit unit CU4 may control an operation of the fourth type light emitting unit EU4, and the fifth pixel circuit unit CU5 may control an operation of the fifth type light emitting unit EU5.

Circuit connecting lines PCL3 connected to the third pixel circuit unit CU3 or the fourth pixel circuit unit CU4 may correspond to one of the first to third circuit connecting lines PL3r, PL3g, and PL3b illustrated in FIG. 10, another one, and the other one, respectively. The fifth type light emitting unit EU5 and the fifth pixel circuit unit CU5 may overlap each other.

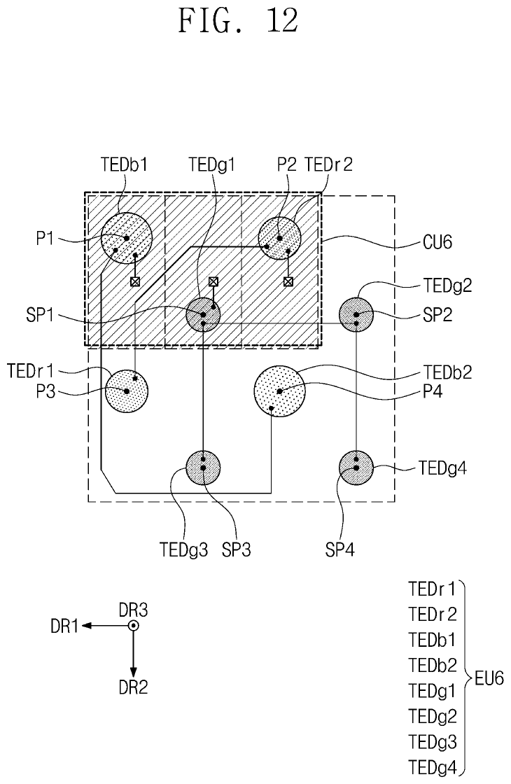

FIG. 12 is a schematic plan view illustrating a light emitting unit and pixel circuits according to an embodiment.

Referring to FIGS. 6 and 12, the sixth type light emitting unit EU6 and the sixth pixel circuit unit CU6 may be disposed in the fourth sub-region SA4. The sixth type light emitting unit EU6 may be referred to as the intermediate light emitting unit. The sixth type light emitting unit EU6 may include eight intermediate light emitting elements TEDr1, TEDr2, TEDb1, TEDb2, TEDg1, TEDg2, TEDg3, and TEDg4 and may have the same arrangement as the second type light emitting unit EU2 described with reference to FIG. 9. Therefore, redundant description thereabout will be omitted for descriptive convenience.

The first color light emitting elements TEDr1 and TEDr2 may have a two-copy structure, the second color light emitting elements TEDg1, TEDg2, TEDg3, and TEDg4 may have a four-copy structure, and the third color light emitting elements TEDb1 and TEDb2 may have a two-copy structure. Accordingly, the number of the pixel circuits included in the sixth pixel circuit unit CU6 may be smaller than the number of the intermediate light emitting elements TEDr1, TEDr2, TEDb1, TEDb2, TEDg1, TEDg2, TEDg3, and TEDg4 included in the sixth type light emitting unit EU6. For example, the eight intermediate light emitting elements TEDr1, TEDr2, TEDb1, TEDb2, TEDg1, TEDg2, TEDg3, and TEDg4 may be included in the sixth type light emitting unit EU6, and three pixel circuits may be included in the sixth pixel circuit unit CU6.

The sixth type light emitting unit EU6 and the sixth pixel circuit unit CU6 may overlap each other. In the fourth sub-region SA4, a pixel circuit for driving light emitting units disposed in another region may not be disposed. Accordingly, in some cases, the fourth sub-region SA4 may be omitted.

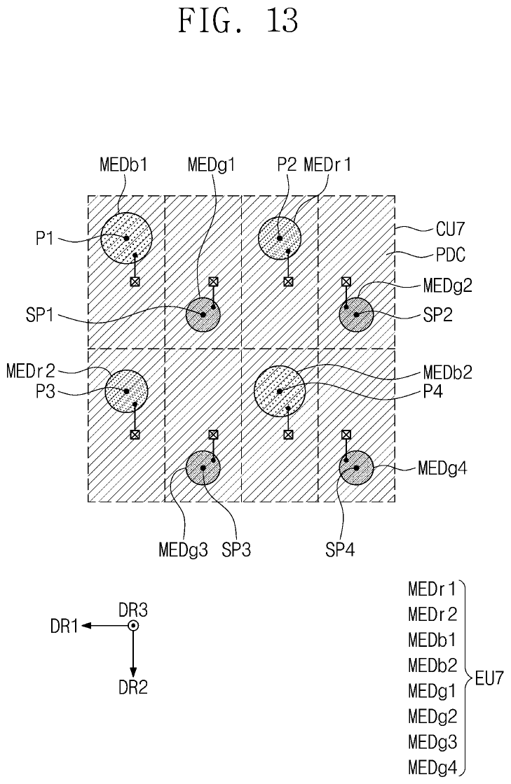

FIG. 13 is a schematic plan view illustrating a light emitting unit and pixel circuits according to an embodiment.

Referring to FIG. 13, the seventh type light emitting unit EU7 and the seventh pixel circuit unit CU7 may be disposed in the second region A2. The seventh type light emitting unit EU7 may be referred to as the main light emitting unit.

The seventh type light emitting unit EU7 may include eight main light emitting elements MEDr1, MEDr2, MEDb1, MEDb2, MEDg1, MEDg2, MEDg3, and MEDg4. The eight main light emitting elements MEDr1, MEDr2, MEDb1, MEDb2, MEDg1, MEDg2, MEDg3, and MEDg4 may include the first color light emitting elements MEDr1 and MEDr2, the second color light emitting elements MEDg1, MEDg2, MEDg3, and MEDg4, and the third color light emitting elements MEDb1 and MEDb2. The number of the second color light emitting elements MEDg1, MEDg2, MEDg3, and MEDg4 may be greater than the number of the (1-2)th light emitting elements EDg1 and EDg2 (refer to FIG. 7A). The first color light emitting elements MEDr1 and MEDr2 may be referred to as the first light emitting elements, the second color light emitting elements MEDg1, MEDg2, MEDg3, and MEDg4 may be referred to as the second light emitting elements, and the third color light emitting elements MEDb1 and MEDb2 may be referred to as the third light emitting elements.

The seventh pixel circuit unit CU7 may control an operation of the seventh type light emitting unit EU7. The seventh pixel circuit unit CU7 may include as many pixel circuits PDC as the main light emitting elements MEDr1, MEDr2, MEDb1, MEDb2, MEDg1, MEDg2, MEDg3, and MEDg4 included in the seventh type light emitting unit EU7. For example, the seventh pixel circuit unit CU7 may include eight pixel circuits PDC. The main light emitting elements MEDr1, MEDr2, MEDb1, MEDb2, MEDg1, MEDg2, MEDg3, and MEDg4 may be electrically connected to the respective pixel circuits PDC in a one-to-one manner. The pixel circuits PDC included in the seventh pixel circuit unit CU7 may be referred to as the main pixel circuits.

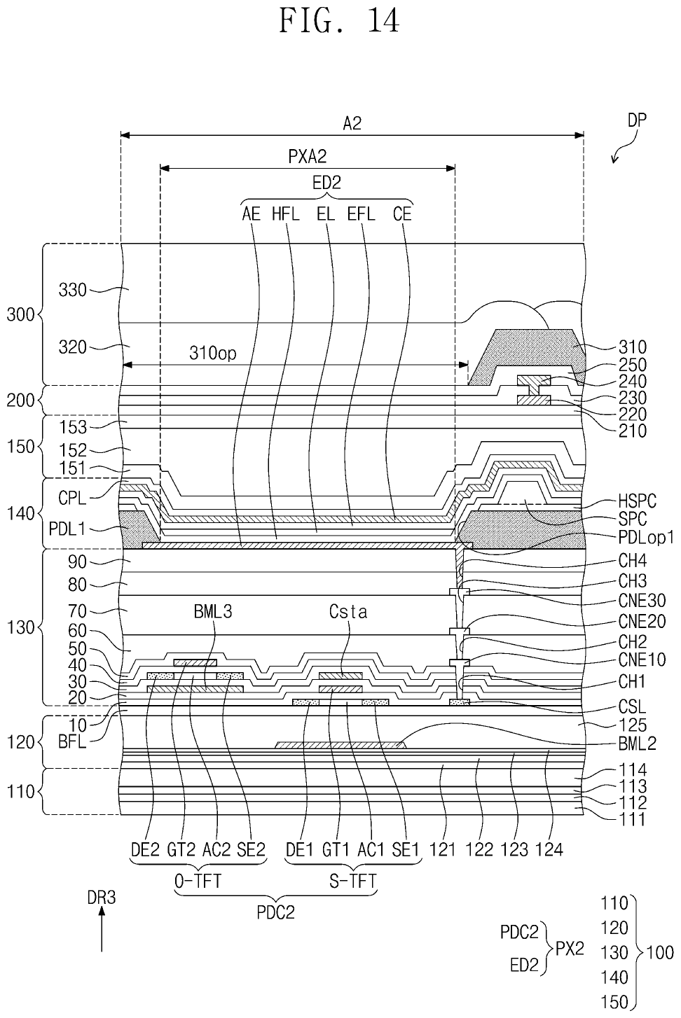

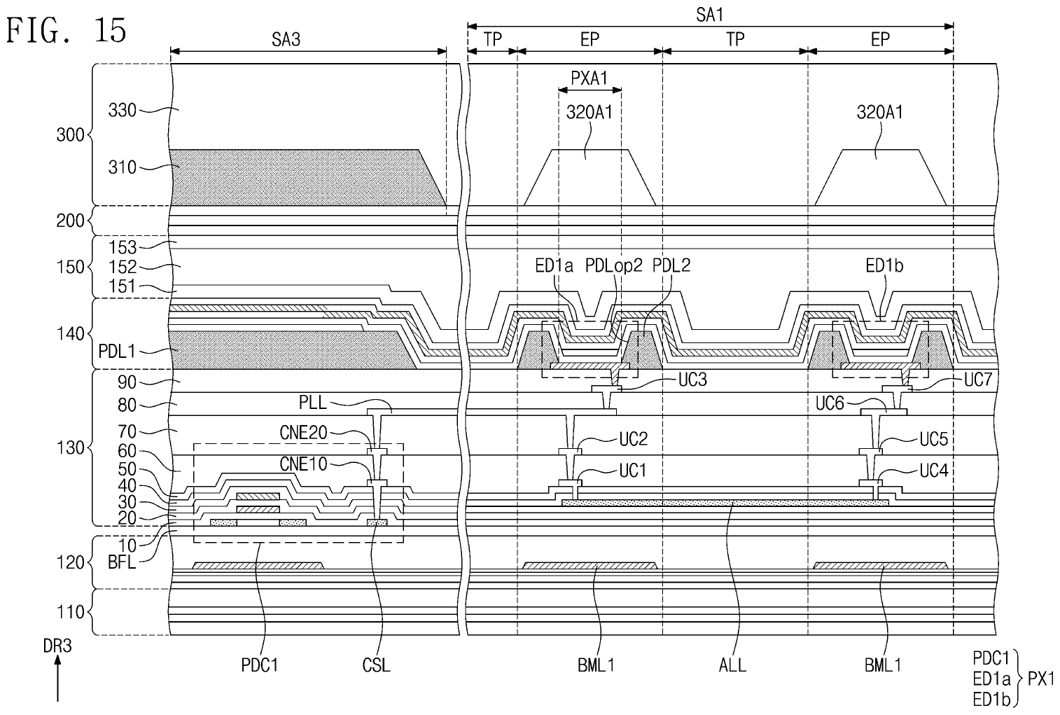

FIG. 14 is a schematic sectional view of the display panel according to an embodiment. FIG. 15 is a schematic sectional view of the display panel according to an embodiment. FIG. 14 is a schematic sectional view of the second region A2, and FIG. 15 is a schematic sectional view illustrating a portion of the first sub-region SA1 and a portion of the third sub-region SA3.

Referring to FIGS. 14 and 15, the display panel DP may include the display layer 100, the sensor layer 200, and an anti-reflection layer 300. The display layer 100 may include a base layer 110, a barrier layer 120, a circuit layer 130, an element layer 140, and an encapsulation layer 150.

The base layer 110 may include first to fourth sub-base layers 111, 112, 113, and 114.

Each of the first sub-base layer 111 and the fourth sub-base layer 114 may include at least one of a polyimide-based resin, an acrylate-based resin, a methacrylate-based resin, a polyisoprene-based resin, a vinyl-based resin, an epoxy-based resin, a urethane-based resin, a celluose-based resin, a siloxane-based resin, a polyamide-based resin, and a perylene-based resin. For example, a “—”-based resin used herein may refer to a resin including a “—” functional group. For example, each of the first and fourth sub-base layers 111 and 114 may include polyimide.

Each of the second sub-base layer 112 and the third sub-base layer 113 may include an inorganic material. For example, each of the second sub-base layer 112 and the third sub-base layer 113 may include at least one of silicon oxide, silicon nitride, silicon oxy-nitride, and amorphous silicon. For example, the second sub-base layer 112 may include silicon oxy-nitride, and the third sub-base layer 113 may include silicon oxide.

The first sub-base layer 111 may be thicker than the fourth sub-base layer 114. For example, the first sub-base layer 111 may have a thickness of about 100,000 angstroms, and the fourth sub-base layer 114 may have a thickness of about 56,000 angstroms. The second sub-base layer 112 may be thinner than the third sub-base layer 113. For example, the second sub-base layer 112 may have a thickness of about 1,000 angstroms, and the third sub-base layer 113 may have a thickness of about 5,000 angstroms. However, the thicknesses of the first to fourth sub-base layers 111, 112, 113, and 114 are not limited to the aforementioned numerical values.

The barrier layer 120 may be disposed on the base layer 110. The barrier layer 120 may include sub-barrier layers 121, 122, 123, 124, and 125, a first lower light blocking layer BML1, and a second lower light blocking layer BML2.

The first and second lower light blocking layers BML1 and BML2 may be referred to as first and second lower layers, first and second lower metal layers, first and second lower electrode layers, first and second lower shielding layers, first and second light blocking layers, first and second metal layers, first and second electrode layers, first and second shielding layers, or first and second overlap layers.

The sub-barrier layers 121, 122, 123, 124, and 125 may include the first sub-barrier layer 121, the second sub-barrier layer 122, the third sub-barrier layer 123, the fourth sub-barrier layer 124, and the fifth sub-barrier layer 125 that are sequentially stacked in a direction away from the base layer 110. Each of the first to fifth sub-barrier layers 121, 122, 123, 124, and 125 may include an inorganic material. For example, each of the first to fifth sub-barrier layers 121, 122, 123, 124, and 125 may include at least one of silicon oxide, silicon nitride, silicon oxy-nitride, and amorphous silicon. For example, the first sub-barrier layer 121 may include silicon oxy-nitride, the second sub-barrier layer 122 may include silicon oxide, the third sub-barrier layer 123 may include amorphous silicon, the fourth sub-barrier layer 124 may include silicon oxide, and the fifth sub-barrier layer 125 may include silicon oxide.

Among the first to fifth sub-barrier layers 121, 122, 123, 124, and 125, the fifth sub-barrier layer 125 may be closest to the circuit layer 130. The fifth sub-barrier layer 125 may be referred to as a top sub-barrier layer. The fifth sub-barrier layer 125 may be thicker than the first to fourth sub-barrier layers 121, 122, 123, and 124. For example, the thickness of the fifth sub-barrier layer 125 may be greater than the sum of the thicknesses of the first to fourth sub-barrier layers 121, 122, 123, and 124. For example, the first sub-barrier layer 121 may have a thickness of about 1,000 angstroms, the second sub-barrier layer 122 may have a thickness of about 500 angstroms, the third sub-barrier layer 123 may have a thickness of about 100 angstroms, the fourth sub-barrier layer 124 may have a thickness of about 130 angstroms, and the fifth sub-barrier layer 125 may have a thickness of about 3,500 angstroms. For example, the thickness of the fifth sub-barrier layer 125 may be greater than the aforementioned thickness.

The first lower light blocking layer BML1 may be disposed in the first region A1, and the second lower light blocking layer BML2 may be disposed in the second region A2. The first lower light blocking layer BML1 and the second lower light blocking layer BML2 may be electrically insulated from each other, and different signals may be applied to the first lower light blocking layer BML1 and the second lower light blocking layer BML2. For example, a constant voltage having a certain voltage level may be applied to the first lower light blocking layer BML1, and the first drive voltage ELVDD (refer to FIG. 5) provided to the pixel circuit PDC (refer to FIG. 5) may be provided to the second lower light blocking layer BML2.

The first lower light blocking layer BML1 and the second lower light blocking layer BML2 may be disposed on the same layer and may include the same material. For example, the first lower light blocking layer BML1 and the second lower light blocking layer BML2 may be disposed between the fourth sub-barrier layer 124 and the fifth sub-barrier layer 125. The first lower light blocking layer BML1 and the second lower light blocking layer BML2 may be covered by the fifth sub-barrier layer 125. Since the fifth sub-barrier layer 125 has the largest thickness among the first to fifth sub-barrier layers 121, 122, 123, 124, and 125, the degree to which characteristics of transistors are changed by the voltages provided to the first and second lower light blocking layers BML1 and BML2 may be decreased.

The first lower light blocking layer BML1 may not overlap the transmissive region TP. In the first sub-region SA1, a region overlapping the first lower light blocking layer BML1 may be defined as an element region EP, and a region not overlapping the first lower light blocking layer BML1 may be defined as the transmissive region TP. The first type light emitting units EU1 (refer to FIG. 6) may be disposed in the element region EP and may be spaced apart from the transmissive region TP.

A buffer layer BFL may be disposed on the barrier layer 120. The buffer layer BFL may be provided in both the first region A1 and the second region A2. The buffer layer BFL may prevent diffusion (or permeation) of metal atoms or impurities from the base layer 110 to a first semiconductor pattern layer. Furthermore, the buffer layer BFL may allow the first semiconductor pattern layer to be uniformly formed, by adjusting the speed at which heat is provided during a crystallization process for forming the first semiconductor pattern layer.

The buffer layer BFL may include inorganic layers. For example, the buffer layer BFL may include a first sub-buffer layer including silicon nitride and a second sub-buffer layer disposed on the first sub-buffer layer and including silicon oxide.

A second pixel PX2 is illustrated in FIG. 14, and a first pixel PX1 is illustrated in FIG. 15. The first pixel PX1 may include a first pixel circuit PDC1 and first light emitting elements ED1a and ED1b electrically connected to the first pixel circuit PDC1. The second pixel PX2 may include a second light emitting element ED2 and a second pixel circuit PDC2. The light emitting elements ED1a and ED1b may be disposed in the first sub-region SA1, and the first pixel circuit PDC1 may be disposed in the third sub-region SA3. The second light emitting element ED2 and the second pixel circuit PDC2 may be disposed in the second region A2.

The second light emitting element ED2 illustrated in FIG. 14 may be one of the eight main light emitting elements MEDr1, MEDr2, MEDb1, MEDb2, MEDg1, MEDg2, MEDg3, and MEDg4, and the second pixel circuit PDC2 may be a pixel circuit (e.g., a single pixel circuit) electrically connected to the one of the eight main light emitting elements MEDr1, MEDr2, MEDb1, MEDb2, MEDg1, MEDg2, MEDg3, and MEDg4.

The first light emitting elements ED1a and ED1b illustrated in FIG. 15 may be a single light emitting element included in the first type light emitting unit EU1 (refer to FIG. 6) and another light emitting element electrically connected thereto, and the first pixel circuit PDC1 may be the single light emitting element and a single pixel circuit electrically connected thereto. For example, the first light emitting elements ED1a and ED1b may be the (1-2)th light emitting elements EDg1 and EDg2 illustrated in FIG. 7A, and the first pixel circuit PDC1 may one of the (1-1)th pixel circuit PDC1-1, the (1-2)th pixel circuit PDC1-2, and the (1-3)th pixel circuit PDC1-3 that are illustrated in FIG. 10.

The circuit layer 130 may be disposed on the buffer layer BFL, and the element layer 140 may be disposed on the circuit layer 130.

Referring to FIG. 14, a silicon thin film transistor S-TFT and an oxide thin film transistor O-TFT of the first pixel circuit PDC1 are illustrated as an example. The silicon thin film transistor S-TFT may be one of the first, second, fifth, sixth, and seventh transistors T1, T2, T5, T6, and T7 described with reference to FIG. 5, and the oxide thin film transistor O-TFT may be one of the third and fourth transistors T3 and T4.

Referring to FIGS. 14 and 15, the first semiconductor pattern layer may be disposed on the buffer layer BFL. The first semiconductor pattern layer may include a silicon semiconductor. For example, the silicon semiconductor may include amorphous silicon or polycrystalline silicon. For example, the first semiconductor pattern layer may include low-temperature poly silicon.

FIGS. 14 and 15 illustrates only a portion of the first semiconductor pattern layer disposed on the buffer layer BFL, and the first semiconductor pattern layer may be additionally disposed in another region. The first semiconductor pattern layer may be arranged across pixels according to a specific rule (or pattern). The first semiconductor pattern layer may have different electrical properties according to whether the first semiconductor pattern layer is doped or not. The first semiconductor pattern layer may include a first region having a high conductivity and a second region having a low conductivity. The first region may be doped with an N-type dopant or a P-type dopant. A P-type transistor may include a doped region that is doped with a P-type dopant, and an N-type transistor may include a doped region that is doped with an N-type dopant. The second region may be an undoped region, or may be a region more lightly doped than the first region.

The first region may have a higher conductivity than the second region and may substantially function as an electrode or a signal line. The second region may substantially correspond to an active region (or, a channel) of a transistor. For example, a portion of the first semiconductor pattern layer may be an active region of the transistor, another portion may be a source or drain of the transistor, and another portion may be a connecting electrode or a connecting signal line.

A source region SE1, an active region AC1, and a drain region DE1 of the silicon thin film transistor S-TFT may be formed from the first semiconductor pattern layer. The source region SE1 and the drain region DE1 may extend from the active region AC1 in opposite directions on the section.

In FIGS. 14 and 15, a portion of a connecting signal line CSL formed from the first semiconductor pattern layer is illustrated. The connecting signal line CSL may be electrically connected to the second node N2 (refer to FIG. 5).

The circuit layer 130 may include inorganic layers and organic layers. In an embodiment, first to fifth insulating layers 10, 20, 30, 40, and 50 sequentially stacked on the buffer layer BFL may be inorganic layers, and sixth to ninth insulating layers 60, 70, 80, and 90 may be organic layers.

The first insulating layer 10 may be disposed on the buffer layer BFL. The first insulating layer 10 may cover the first semiconductor pattern layer. The first insulating layer 10 may be an inorganic layer and/or an organic layer and may have a single-layer structure or a multi-layer structure. The first insulating layer 10 may include at least one of aluminum oxide, titanium oxide, silicon oxide, silicon nitride, silicon oxy-nitride, zirconium oxide, and hafnium oxide. In this embodiment, the first insulating layer 10 may be a single silicon oxide layer. Not only the first insulating layer 10 but also the insulating layers of the circuit layer 130 to be described below may have a single-layer structure or a multi-layer structure.

A gate electrode GT1 of the silicon thin film transistor S-TFT may be disposed on the first insulating layer 10. The gate electrode GT1 may be a portion of a metal pattern layer. The gate electrode GT1 may overlap the active region AC1. The gate electrode GT1 may function as a mask in a process of doping the first semiconductor pattern layer. The gate electrode GT1 may include titanium, silver, an alloy containing silver, molybdenum, an alloy containing molybdenum, aluminum, an alloy containing aluminum, aluminum nitride, tungsten, tungsten nitride, copper, indium tin oxide, or indium zinc oxide, but embodiments are not limited thereto.

The second insulating layer 20 may be disposed on the first insulating layer 10 and may cover the gate electrode GT1. The second insulating layer 20 may be an inorganic layer and may have a single-layer structure or a multi-layer structure. The second insulating layer 20 may include at least one of silicon oxide, silicon nitride, and silicon oxy-nitride. In this embodiment, the second insulating layer 20 may have a single-layer structure including a silicon nitride layer.

The third insulating layer 30 may be disposed on the second insulating layer 20. The third insulating layer 30 may be an inorganic layer and may have a single-layer structure or a multi-layer structure. For example, the third insulating layer 30 may have a multi-layer structure including a silicon oxide layer and a silicon nitride layer. An electrode Csta of the first capacitor Cst (refer to FIG. 5) may be disposed between the second insulating layer 20 and the third insulating layer 30. Furthermore, another electrode of the first capacitor Cst may be disposed between the first insulating layer 10 and the second insulating layer 20.

A second semiconductor pattern layer may be disposed on the third insulating layer 30. The second semiconductor pattern layer may include an oxide semiconductor. The oxide semiconductor may include regions distinguished according to whether metal oxide is reduced or not. A region where metal oxide is reduced (hereinafter, referred to as the reduced region) may have a higher conductivity than a region where metal oxide is not reduced (hereinafter, referred to as the non-reduced region). The reduced region substantially may function as a source/drain of a transistor or a signal line. The non-reduced region substantially corresponds to an active region (e.g., a semiconductor region or a channel) of the transistor. For example, a portion of the second semiconductor pattern layer may be an active region of the transistor, another portion may be a source/drain region of the transistor, and another portion may be a signal transmission region.

A source region SE2, an active region AC2, and a drain region DE2 of the oxide thin film transistor O-TFT may be formed from the second semiconductor pattern layer. The source regions SE2 and the drain regions DE2 may extend from the active regions AC2 in opposite directions on the section. A third lower light blocking layer BML3 may be disposed in the second region A2, and may be disposed on the second insulating layer 20 and disposed under the source region SE2, the active region AC2, and the drain region DE2 of the oxide thin film transistor O-TFT. For example, the third lower light blocking layer BML3 may be disposed at a higher level than the first lower light blocking layer BML1 and the second lower light blocking layer BML2.

A connecting line ALL electrically connecting the first light emitting elements ED1a and ED1b may be formed from the second semiconductor pattern layer. For example, the connecting line ALL may be formed by reducing the second semiconductor pattern layer. The connecting line ALL may include indium gallium zinc oxide (IGZO). However, a constituent material of the connecting line ALL is not limited thereto.

A first light emitting element ED1a may be electrically connected to the connecting line ALL through first to third connecting pattern layers UC1, UC2, and UC3 and a circuit connecting line PLL. Another first light emitting element ED1b may be electrically connected to the connecting line ALL through fourth to seventh connecting pattern layers UC4, UC5, UC6, and UC7.

The fourth insulating layer 40 may be disposed on the third insulating layer 30. The fourth insulating layer 40 may cover the second semiconductor pattern layer. The fourth insulating layer 40 may be an inorganic layer and may have a single-layer structure or a multi-layer structure. The fourth insulating layer 40 may include at least one of aluminum oxide, titanium oxide, silicon oxide, silicon nitride, silicon oxy-nitride, zirconium oxide, and hafnium oxide. In an embodiment, the fourth insulating layer 40 may have a single-layer structure including silicon oxide.

A gate electrode GT2 of the oxide thin film transistor O-TFT may be disposed on the fourth insulating layer 40. The gate electrode GT2 may be a portion of a metal pattern layer. The gate electrode GT2 may overlap the active region AC2. The gate electrode GT2 may function as a mask in a process of reducing the second semiconductor pattern layer.

The fifth insulating layer 50 may be disposed on the fourth insulating layer 40 and may cover the gate electrode GT2. The fifth insulating layer 50 may be an inorganic layer and/or an organic layer and may have a single-layer structure or a multi-layer structure. For example, the fifth insulating layer 50 may have a multi-layer structure including a silicon oxide layer and a silicon nitride layer.

A first connecting electrode CNE10 may be disposed on the fifth insulating layer 50. The first connecting electrode CNE10 may be connected to the connecting signal line CSL through a first contact hole CH1 penetrating the first to fifth insulating layers 10, 20, 30, 40, and 50.

The first connecting pattern layer UC1 and the fourth connecting pattern layer UC4 may be disposed on the fifth insulating layer 50. The first connecting pattern layer UC1 and the fourth connecting pattern layer UC4 may pass through the fourth and fifth insulating layers 40 and 50 and may be connected to the connecting line ALL.

The sixth insulating layer 60 may be disposed on the fifth insulating layer 50. A second connecting electrode CNE20 may be disposed on the sixth insulating layer 60. The second connecting electrode CNE20 may be connected to the first connecting electrode CNE10 through a second contact hole CH2 penetrating the sixth insulating layer 60. The second connecting pattern layer UC2 and the fifth connecting pattern layer UC5 may be disposed on the sixth insulating layer 60. The second connecting pattern layer UC2 may pass through the sixth insulating layer 60 and may be connected to the first connecting pattern layer UC1, and the fifth connecting pattern layer UC5 may pass through the sixth insulating layer 60 and may be connected to the fourth connecting pattern layer UC4.

The seventh insulating layer 70 may be disposed on the sixth insulating layer 60 and may cover the second connecting electrode CNE20, the second connecting pattern layer UC2, and the fifth connecting pattern layer UC5.

A third connecting electrode CNE30 may be disposed on the seventh insulating layer 70. The third connecting electrode CNE30 may be connected to the second connecting electrode CNE20 through a third contact hole CH3 penetrating the seventh insulating layer 70. The sixth connecting pattern layer UC6 may be disposed on the seventh insulating layer 70. The sixth connecting pattern layer UC6 may pass through the seventh insulating layer 70 and may be connected to the fifth connecting pattern layer UC5.

The circuit connecting line PLL may be disposed on the seventh insulating layer 70. The circuit connecting line PLL may pass through the seventh insulating layer 70 in the third sub-region SA3 and may be connected to the second connecting electrode CNE20 electrically connected to the first pixel circuit PDC1. Furthermore, the circuit connecting line PLL may pass through the seventh insulating layer 70 in the first sub-region SA1 and may be connected to the second connecting pattern layer UC2 of the first sub-region SAL

The circuit connecting line PLL may be one of the first circuit connecting line PL1r, the second circuit connecting line PL1g, and the third circuit connecting line PL1b that are illustrated in FIGS. 7A to 7F. For example, the circuit connecting line PLL may be the second circuit connecting line PL1g.

The circuit connecting line PLL, the third connecting electrode CNE30, and the sixth connecting pattern layer UC6 may include a transparent conductive material. The transparent conductive line may include a transparent conductive material or a light transmissive material. For example, the circuit connecting line PLL, the third connecting electrode CNE30, and the sixth connecting pattern layer UC6 may be formed of transparent conductive oxide (TCO), such as indium tin oxide (ITO), indium zinc oxide (IZO), indium gallium zinc oxide (IGZO), zinc oxide (ZnO), or indium oxide (In₂O₃). Accordingly, light may pass through the circuit connecting line PLL even though the circuit connecting line PLL overlaps the transmissive region TP.

The eighth insulating layer 80 may be disposed on the seventh insulating layer 70 and may cover the third connecting electrode CNE30 and the circuit connecting line PLL. The third connecting pattern layer UC3 and the seventh connecting pattern layer UC7 may be disposed on the eighth insulating layer 80. The third connecting pattern layer UC3 may pass through the eighth insulating layer 80 and may be connected to the circuit connecting line PLL, and the seventh connecting pattern layer UC7 may pass through the eighth insulating layer 80 and may be connected to the sixth connecting pattern layer UC6. The third connecting pattern layer UC3 and the seventh connecting pattern layer UC7 may include the aforementioned transparent conductive material.

The ninth insulating layer 90 may be disposed on the eighth insulating layer 80 and may cover the third connecting pattern layer UC3 and the seventh connecting pattern layer UC7.

The circuit connecting line PLL may be disposed between the seventh insulating layer 70 and the eighth insulating layer 80, but embodiments are not limited thereto. For example, the circuit connecting line PLL may be disposed between the eighth insulating layer 80 and the ninth insulating layer 90. In a display panel DP (refer to FIG. 4), some of the circuit connecting lines PLL may be disposed between the seventh insulating layer 70 and the eighth insulating layer 80, and the others may be disposed between the eighth insulating layer 80 and the ninth insulating layer 90.

Each of the sixth insulating layer 60, the seventh insulating layer 70, the eighth insulating layer 80, and the ninth insulating layer 90 may be an organic layer. For example, each of the sixth insulating layer 60, the seventh insulating layer 70, the eighth insulating layer 80, and the ninth insulating layer 90 may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylate-based polymer, an imide-based polymer, an aryl ether-based polymer, an amide-based polymer, a fluorine-based polymer, a p-xylene-based polymer, a vynyl alcohol-based polymer, or a blend thereof.

Referring to FIGS. 14 and 15, the element layer 140 including the first light emitting elements ED1a and ED1b and the second light emitting element ED2 may be disposed on the circuit layer 130. Each of the first light emitting elements ED1a and ED1b and the second light emitting element ED2 may include a pixel electrode AE (or, an anode), a first functional layer HFL, an emissive layer EL, a second functional layer EFL, and a common electrode CE (or, a cathode). The first functional layer HFL, the second functional layer EFL, and the common electrode CE may be commonly provided for the pixels PX (refer to FIG. 4).

The first electrode AE may be disposed on the eighth insulating layer 80. The pixel electrode AE of the second light emitting element ED2 may be connected to the second connecting electrode CNE20 electrically connected to the second pixel circuit PDC2 through a fourth contact hole CH4 penetrating the eighth insulating layer 80 and the ninth insulating layer 90. The first light emitting element ED1a may pass through the ninth insulating layer 90 and may be electrically connected to the third connecting pattern layer UC3, and the first light emitting element ED1b may pass through the ninth insulating layer 90 and may be electrically connected to the seventh connecting pattern layer UC7.

The pixel electrode AE may be a transflective electrode, a transmissive electrode, or a reflective electrode. In an embodiment, the pixel electrode AE may include a reflective layer formed of silver, magnesium, aluminum, platinum, palladium, gold, nickel, neodymium, iridium, chromium, or a compound thereof and a transparent or translucent electrode layer formed on the reflective layer. The transparent or translucent electrode layer may include at least one selected from the group including indium tin oxide, indium zinc oxide, indium gallium zinc oxide, zinc oxide, or indium oxide and aluminum-doped zinc oxide. For example, the pixel electrode AE may include a multi-layer structure in which indium tin oxide, silver, and indium tin oxide are sequentially stacked.

A pixel defining layer PDL1 and a pixel defining pattern layer PDL2 may be disposed on the ninth insulating layer 90. Referring to FIG. 6 together, the pixel defining layer PDL1 may be disposed in the second to fourth sub-regions SA2, SA3, and SA4 and the second region A2, and the pixel defining pattern layer PDL2 may be disposed in the first sub-region SAL

The pixel defining layer PDL1 and the pixel defining pattern layer PDL2 may have a property of absorbing light. For example, the pixel defining layer PDLs and the pixel defining pattern layer PDL2 may be black in color. The pixel defining layer PDL1 and the pixel defining pattern layer PDL2 may include a black coloring agent. The black coloring agent may include a black dye or a black pigment. The black coloring agent may include carbon black, metal such as chromium, or oxide thereof.

The pixel defining layer PDL1 may have an opening PDLop1 defined therein through which a portion of the pixel electrode AE is exposed, and the pixel defining pattern layer PDL2 may have an opening PDLop2 formed therein through which a portion of the pixel electrode AE is exposed. For example, each of the pixel defining layer PDL1 and the pixel defining pattern layer PDL2 may cover the periphery of the corresponding pixel electrode AE. Emissive regions may be defined by the openings PDLop1 and PDLop2 defined in the pixel defining layer PDL1 and the pixel defining pattern layer PDL2. For example, a first emissive region PXA1 may be defined in each of the first light emitting elements ED1a and ED1b, and a second light emitting region PXA2 may be defined in the second light emitting element ED2.

A spacer HSPC may be disposed on the pixel defining layer PDL1. A protruding spacer SPC may be disposed on the spacer HSPC. The spacer HSPC and the protruding spacer SPC may be integrally formed with each other and may be formed of the same material. For example, the spacer HSPC and the protruding spacer SPC may be formed through the same process by a half-tone mask. However, this is an example, and embodiments are not limited thereto. For example, the spacer HSPC and the protruding spacer SPC may include different materials and may be formed by separate processes.

The height (or thickness) of the protruding spacer SPC may be greater than the height (or, thickness) of the spacer HSPC. The height of the spacer HSPC may range from about 0.1 μm to about 0.5 μm, and the total height of the spacer HSPC and the protruding spacer SPC may range from about 1.1 μm to about 2.0 μm. However, the height of the spacer HSPC and the total height of the spacer HSPC and the protruding spacer SPC are not limited to the aforementioned examples.

The first functional layer HFL may be disposed on the pixel electrode AE, the pixel defining layer PDL1, the pixel defining pattern layer PDL2, the spacer HSPC, and the protruding spacer SPC. The first functional layer HFL may include a hole transport layer (HTL), may include a hole injection layer (HIL), or may include both the hole transport layer and the hole injection layer. The first functional layer HFL may be disposed in the entire display region DP-DA (refer to FIG. 4).

The emissive layer EL may be disposed on the first functional layer HFL and may be disposed in a region corresponding to the opening PDLop1 or PDLop2 of the pixel defining layer PDL1 or the pixel defining pattern layer PDL2. The emissive layer EL may include an organic material, an inorganic material, or an organic-inorganic material that emits certain colored light.

The second functional layer EFL may be disposed on the first functional layer HFL and may cover the emissive layer EL. The second functional layer EFL may include an electron transport layer (ETL), may include an electron injection layer (EIL), or may include both the electron transport layer and the electron injection layer. The second functional layer EFL may be disposed in the entire display region DP-DA (refer to FIG. 4).

The common electrode CE may be disposed on the second functional layer EFL. The common electrode CE may be disposed in the display region DP-DA (refer to FIG. 4).

The element layer 140 may further include a capping layer CPL disposed on the common electrode CE. The capping layer CPL may function to improve light emission efficiency by the principle of constructive interference. The capping layer CPL may include, for example, a material having a refractive index of about 1.6 or more for light having a wavelength of about 589 nm. The capping layer CPL may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or a combination thereof. A substituent including O, N, S, Se, Si, F, Cl, Br, I, or a combination thereof may be selectively substituted for the carbocyclic compound, the heterocyclic compound, and the amine group-containing compound.

The encapsulation layer 150 may be disposed on the element layer 140. The encapsulation layer 150 may include an inorganic layer 151, an organic layer 152, and an inorganic layer 153 sequentially stacked one above another. However, layers of the encapsulation layer 150 are not limited thereto.

The inorganic layers 151 and 153 may protect the element layer 140 from moisture and oxygen, and the organic layer 152 may protect the element layer 140 from foreign matter such as dust particles. The inorganic layers 151 and 153 may include a silicon nitride layer, a silicon oxy-nitride layer, a silicon oxide layer, a titanium oxide layer, or an aluminum oxide layer. The organic layer 152 may include an acrylate-based organic layer, but embodiments are not limited thereto.

The sensor layer 200 may be disposed on the display layer 100. The sensor layer 200 may be referred to as a sensor, an input sensing layer, or an input sensing panel. The sensor layer 200 may include a sensor base layer 210, a first sensor conductive layer 220, a sensor insulating layer 230, a second sensor conductive layer 240, and a sensor cover layer 250.

The sensor base layer 210 may be disposed (e.g., directly disposed) on the display layer 100. The sensor base layer 210 may be an inorganic layer including at least one of silicon nitride, silicon oxy-nitride, and silicon oxide. In another example, the sensor base layer 210 may be an organic layer including an epoxy resin, an acrylic resin, or an imide-based resin. The sensor base layer 210 may have a single-layer structure, or may have a multi-layer structure stacked in the third direction DR3.

Each of the first sensor conductive layer 220 and the second sensor conductive layer 240 may have a single-layer structure, or may have a multi-layer structure stacked in the third direction DR3.

The conductive layer having the single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide, indium zinc oxide, zinc oxide, or indium zinc tin oxide. For example, the transparent conductive layer may include a conductive polymer such as poly(3,4-ethylenedioxythiophene) (PEDOT), a metal nano wire, or graphene.

The conductive layer having the multi-layer structure may include metal layers. The meal layers may have, for example, a three-layer structure of titanium/aluminum/titanium. The conductive layer having the multi-layer structure may include at least one metal layer and at least one transparent conductive layer.

The sensor insulating layer 230 may be disposed between the first sensor conductive layer 220 and the second sensor conductive layer 240. The sensor insulating layer 230 may include an inorganic film. The inorganic film may include at least one of aluminum oxide, titanium oxide, silicon oxide, silicon nitride, silicon oxy-nitride, zirconium oxide, and hafnium oxide.

In another example, the sensor insulating layer 230 may include an organic film. The organic film may include at least one of an acrylate-based resin, a methacrylate-based resin, a polyisoprene-based resin, a vinyl-based resin, an epoxy-based resin, a urethane-based resin, a celluose-based resin, a siloxane-based resin, a polyimide-based resin, a polyamide-based resin, and a perylene-based resin.

The sensor cover layer 250 may be disposed on the sensor insulating layer 230 and may cover the second sensor conductive layer 240. The second sensor conductive layer 240 may include a conductive pattern layer. The sensor cover layer 250 may cover the conductive pattern layer and may reduce or eliminate a probability of damage to the conductive pattern layer in a subsequent process. The sensor cover layer 250 may include an inorganic material. For example, the sensor cover layer 250 may include silicon nitride, but embodiments are not limited thereto. In another example, the sensor cover layer 250 may be omitted.

The anti-reflection layer 300 may be disposed on the sensor layer 200. The anti-reflection layer 300 may include a dividing layer 310, color filters 320 and 320A1, and a planarization layer 330. The dividing layer 310 and the color filters 320 and 320A1 may not be disposed in the transmissive region TP of the first sub-region SAL

The dividing layer 310 may be disposed to overlap the conductive pattern layer of the second sensor conductive layer 240. The sensor cover layer 250 may be disposed between the dividing layer 310 and the second sensor conductive layer 240. The dividing layer 310 may prevent reflection of external light by the second sensor conductive layer 240. A material of the dividing layer 310 is not limited as long as it is a material capable of absorbing light. The dividing layer 310 may be a layer having a black color. In an embodiment, the dividing layer 310 may include a black coloring agent. The black coloring agent may include a black dye or a black pigment. The black coloring agent may include carbon black, metal such as chromium, or oxide thereof.

Referring to FIG. 6 together, the dividing layer 310 may be disposed in the second to fourth sub-regions SA2, SA3, and SA4 and the second region A2. For example, the dividing layer 310 may not overlap the first sub-region SAL The dividing layer 310 may have dividing openings 310op formed therein. The dividing openings 310op may overlap the emissive layers EL disposed in the second to fourth sub-regions SA2, SA3, and SA4. In the second to fourth sub-regions SA2, SA3, and SA4 and the second region A2, the color filters 320 may be disposed to correspond to (or overlapping) the dividing openings 310op. The color filters 320 may transmit light provided from the emissive layers EL overlapping the color filters 320.

In the first sub-region SA1, the color filters 320A1 may be arranged to overlap the first light emitting elements ED1a and ED1b. The color filters 320A1 may be spaced apart from the dividing layer 310. For example, the color filters 320A1 may not make contact with the dividing layer 310.

The planarization layer 330 may cover the dividing layer 310 and the color filters 320 and 320A1. The planarization layer 330 may include an organic material and may provide a flat surface on an upper surface of the planarization layer 330. In another example, the planarization layer 330 may be omitted.

In an embodiment, the anti-reflection layer 300 may include a reflection control layer instead of the color filters 320 and 320A1. For example, in FIGS. 14 and 15, the color filters 320 and 320A1 may be omitted, and the reflection control layer may be added to the places where the color filters 320 and 320A1 are omitted. The reflection control layer may selectively absorb light in a partial band of light reflected inside the display panel and/or the electronic device or light in a partial band of light incident from outside the display panel and/or the electronic device.

For example, the reflection control layer may absorb light in a first wavelength region of about 490 nm to about 505 nm and a second wavelength region of about 585 nm to about 600 nm, and thus the light transmittance in the first wavelength region and the second wavelength region may be about 40% or less. The reflection control layer may absorb light outside the wavelength ranges of red light, green light, and blue light emitted from the emissive layers EL. Since the reflection control layer absorbs light outside the wavelength range of the red light, the green light, or the blue light emitted from the emissive layers EL as described above, a decrease in the luminance of the display panel and/or the electronic device may be prevented or minimized. For example, deterioration in the light emission efficiency of the display panel and/or the electronic device may be prevented or minimized, and visibility may be improved.

The reflection control layer may be implemented with an organic layer including a dye, a pigment, or a combination thereof. The reflection control layer may include a tetraazaporphyrin (TAP)-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, and a combination thereof.

In an embodiment, the reflection control layer may have a transmittance of about 64% to about 72%. The transmittance of the reflection control layer may be adjusted according to the content of the pigment and/or dye included in the reflection control layer. The reflection control layer may overlap the emissive regions in plan view, but may not overlap the transmissive region TP in plan view.

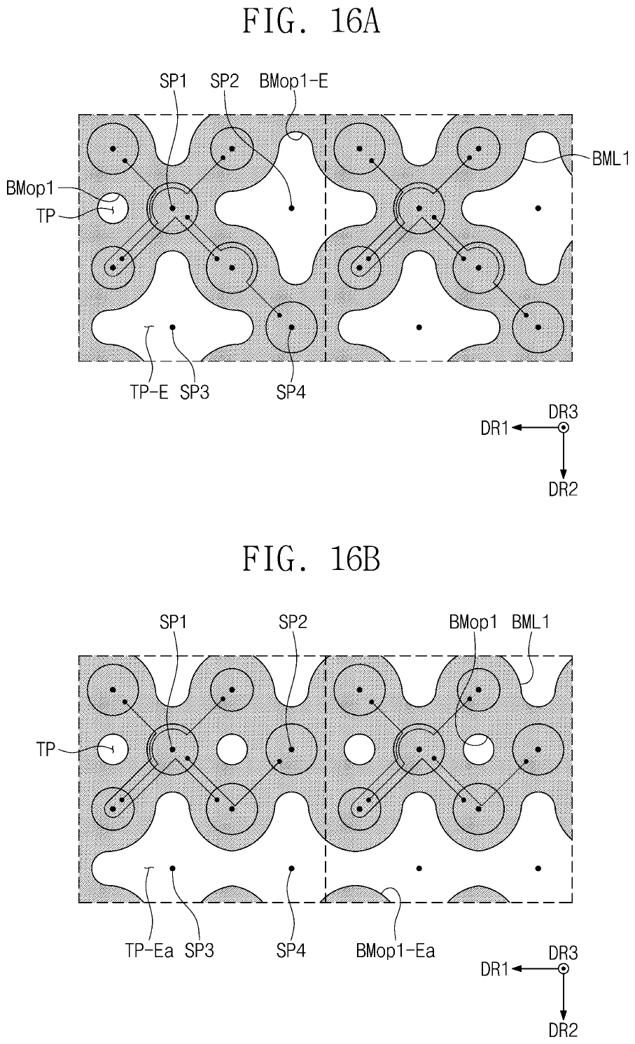

FIG. 16A is a schematic enlarged plan view illustrating a partial region of the display panel according to an embodiment.

Referring to FIGS. 7A and 16A, the first lower light blocking layer BML1 overlapping two first light emitting units EU1a is illustrated.

Openings BMop1 and BMop1-E may be formed in the first lower light blocking layer BML1. The openings BMop1 and BMop1-E may define transmissive regions TP and TP-E. For example, the openings BMop1 and BMop1-E may include the opening BMop1 and the expansion opening BMop1-E.

For example, in the case of the first light emitting unit EU1a, light emitting elements may not be disposed at the second selection point SP2 and the third selection point SP3. The expansion opening BMop1-E may be formed as an expanded opening formed by connecting the second selection point SP2 and openings around the second selection point SP2, or an expanded opening formed by connecting the third selection point SP3 and openings around the third selection point SP3. The expansion opening BMop1-E may have a larger area than the opening B Mop 1.

FIG. 16B is a schematic enlarged plan view illustrating a partial region of the display panel according to an embodiment.

Referring to FIGS. 7B and 16B, a first lower light blocking layer BML1 overlapping two second light emitting units EU1b is illustrated.

Openings BMop1 and BMop1-Ea may be formed in the first lower light blocking layer BML1. The openings BMop1 and BMop1-Ea may define transmissive regions TP and TP-Ea.

The openings BMop1 and BMop1-Ea may include the opening BMop1 and the expansion opening BMop1-Ea. For example, in the case of the second light emitting unit EU1b, light emitting elements may not be disposed at the third selection point SP3 and the fourth selection point SP4. For example, the expanded opening BMop1-Ea formed by connecting openings around the third selection point SP3 and the fourth selection point SP4 may be defined. Accordingly, the expansion opening BMop1-Ea may have a larger area than the opening BMop1.

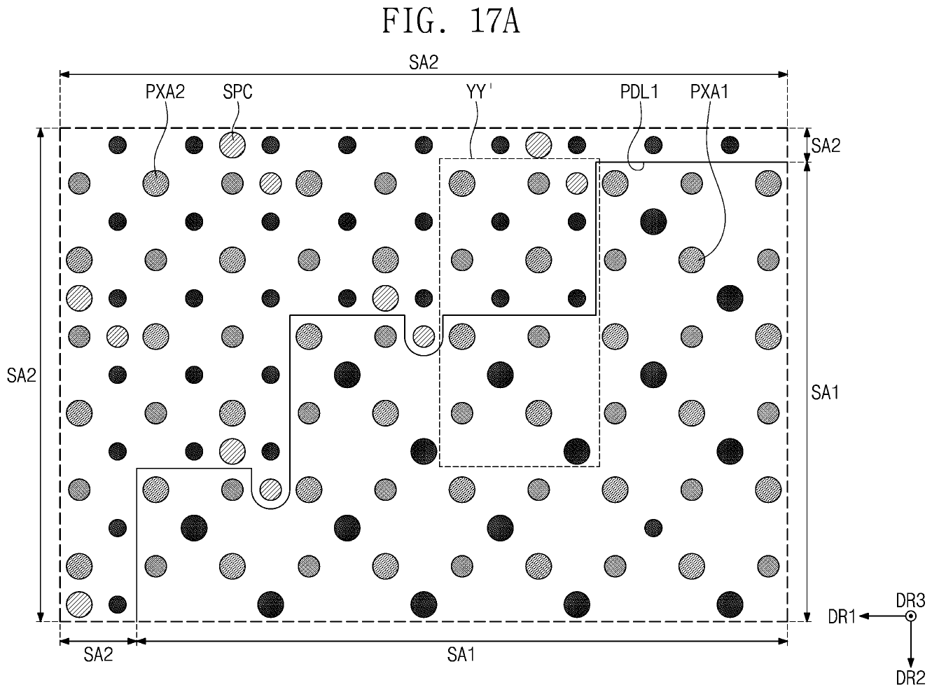

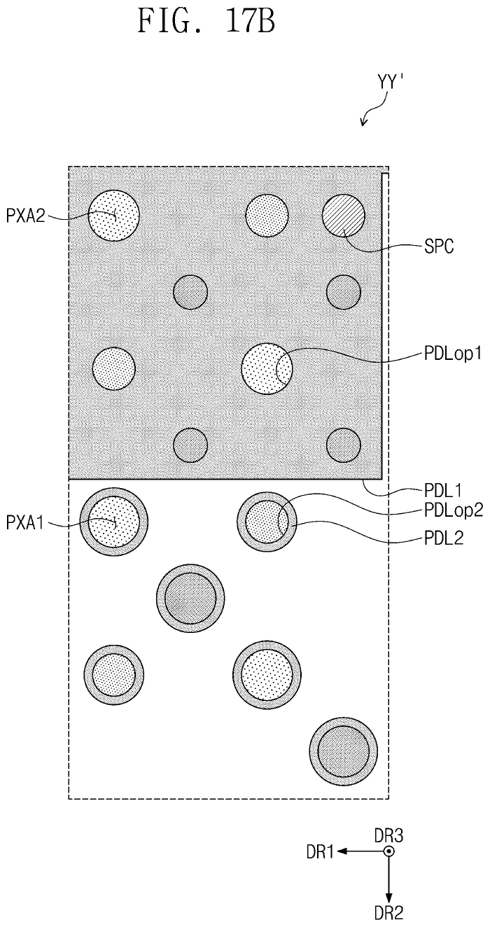

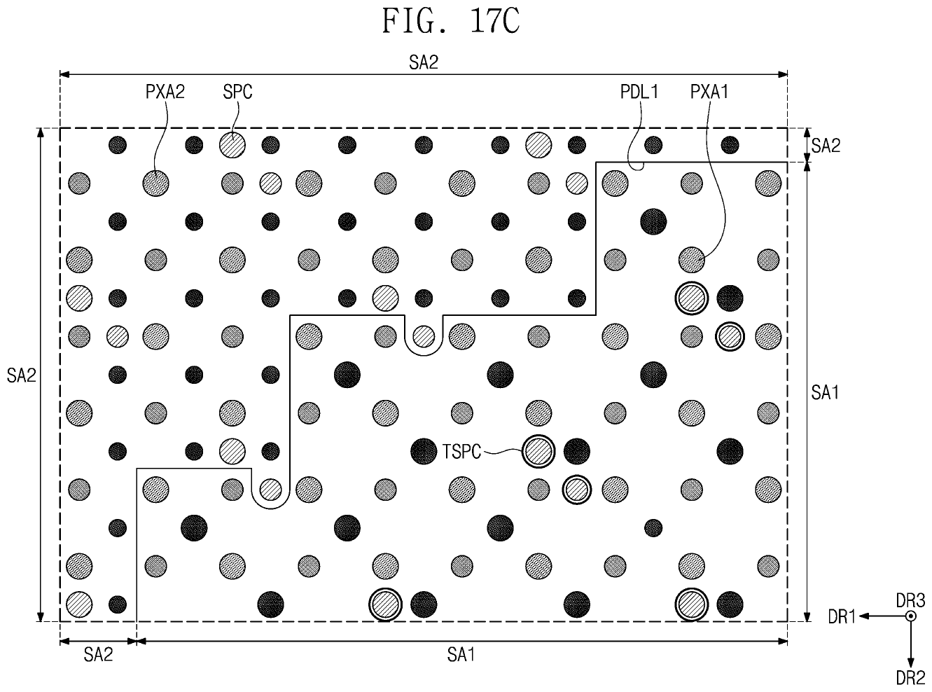

FIG. 17A is a schematic enlarged plan view illustrating a partial region of the display panel according to an embodiment. FIG. 17B is a schematic enlarged plan view illustrating a partial region of the display panel according to an embodiment. FIG. 17B is a schematic enlarged plan view illustrating region YY′ of FIG. 17A.

Referring to FIGS. 14, 17A, and 17B, the spacer HSPC may have a shape substantially corresponding to the pixel defining layer PDL1. For example, the spacer HSPC may be space apart from an edge portion of the pixel defining layer PDL1 and may be disposed on an upper surface of the pixel defining layer PDL1. The protruding spacer SPC may be disposed on the spacer HSPC and may overlap the pixel defining layer PDL1. In plan view, the protruding spacer SPC may have a circular shape in plan view.

Protruding spacers SPC may be provided. For example, two protruding spacers SPC may be disposed adjacent to each other. For example, a probability that a dent defect caused by a mask occurs during a manufacturing process may be further reduced.

Referring to FIG. 6 together, the protruding spacers SPC may be disposed in the second sub-region SA2, the third sub-region SA3, the fourth sub-region SA4, and the second region A2. The protruding spacers SPC may not be disposed in the first sub-region SAL A conductive layer disposed in the circuit layer 130 (refer to FIG. 15) may be smaller in the first sub-region SA1 than in the second to fourth sub-regions SA2, SA3, and SA4 and the second region A2. For example, the first sub-region SA1 may have a relatively concave shape, compared to the other regions. For example, during the manufacturing process, the thickness of the first sub-region SA1 may be smaller than those of the other regions. In another example, during the manufacturing process, an upper surface of the first sub-region SA1 may have a shape concavely recessed toward the base layer 110. Accordingly, the pixel defining pattern layers PDL2 may be spaced apart from the mask without being brought into contact with the mask during the manufacturing process. Thus, in the first sub-region SA1, a dent defect caused by the mask may not occur. As a result, the spacer HSPC and the protruding spacers SPC may be omitted in the first sub-region SAL

In an embodiment, the protruding spacers SPC may also be omitted in at least a part of the second to fourth sub-regions SA2, SA3, and SA4. In another example, the arrangement density of the protruding spacers SPC in the second to fourth sub-regions SA2, SA3, and SA4 may be the same as (or different from) the arrangement density of the protruding spacers SPC in the second region A2. For example, the arrangement density of the protruding spacers SPC in the second region A2 may be higher than the arrangement density of the protruding spacers SPC in the second to fourth sub-regions SA2, SA3, and SA4.

In FIG. 17B, the shape of the pixel defining pattern layer PDL2 in plan view is illustrated. For example, the pixel defining pattern layer PDL2 may have a circular ring shape. However, the shape of the pixel defining pattern layer PDL2 is not limited thereto. For example, the pixel defining pattern layer PDL2 may have various shapes such as an angled ring shape, a ring shape including a straight line, a ring shape including a straight line and a curve, and an irregular ring shape.

FIG. 17C is a schematic enlarged plan view illustrating a partial region of the display panel according to an embodiment.

Referring to FIG. 17C, an additional spacer TSPC may be additionally disposed in the first sub-region SAL The additional spacer TSPC may be disposed on the ninth insulating layer 90 (refer to FIG. 15). The additional spacer TSPC may have a sectional shape similar to the sectional shapes of the spacer HSPC and the protruding spacer SPC illustrated in FIG. 14.

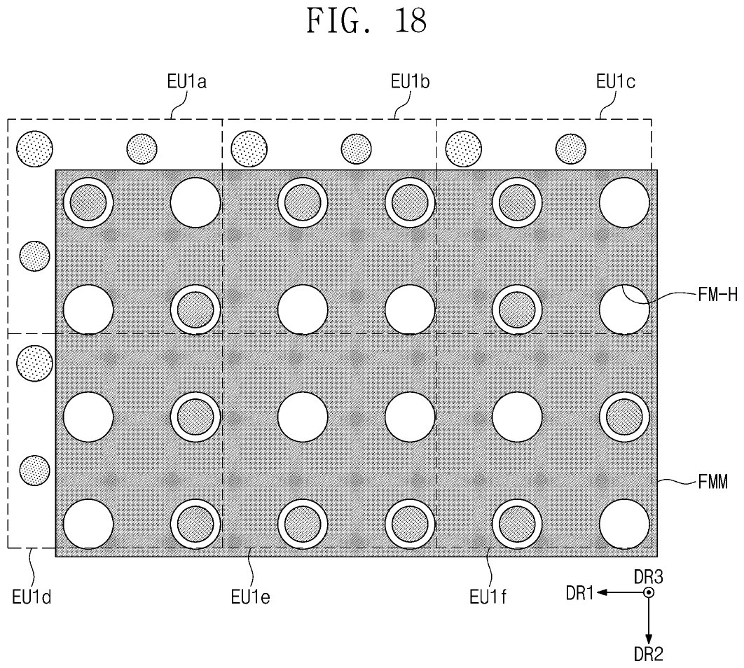

FIG. 18 is a schematic plan view illustrating a step of a manufacturing method of the display panel according to an embodiment.

Referring to FIGS. 6 and 18, the first to sixth light emitting units EU1a, EU1b, EU1c, EU1d, EU1e, and EU1f and a mask FMM overlapping the first to sixth light emitting units EU1a, EU1b, EU1c, EU1d, EU1e, and EU1f are illustrated. The mask FMM may have mask openings FM-H formed therein. The mask openings FM-H may be spaced apart from each other in the first direction DR1 and the second direction DR2 according to a certain rule (or pattern).

According to an embodiment, the first type light emitting units EU1 may include at least two light emitting units having different arrangement rules (or patterns) among the first to sixth light emitting units EU1a, EU1b, EU1c, EU1d, EU1e, and EU1f. As described with reference to FIGS. 7A to 7F, the first type light emitting units EU1 may include at least two of the six combinations implemented with the first to fourth selection points SP1, SP2, SP3, and SP4. For example, light emitting elements disposed in the first sub-region SA1 may have a random arrangement structure, which is a random structure that is able to be designed and manufactured by the mask FMM.

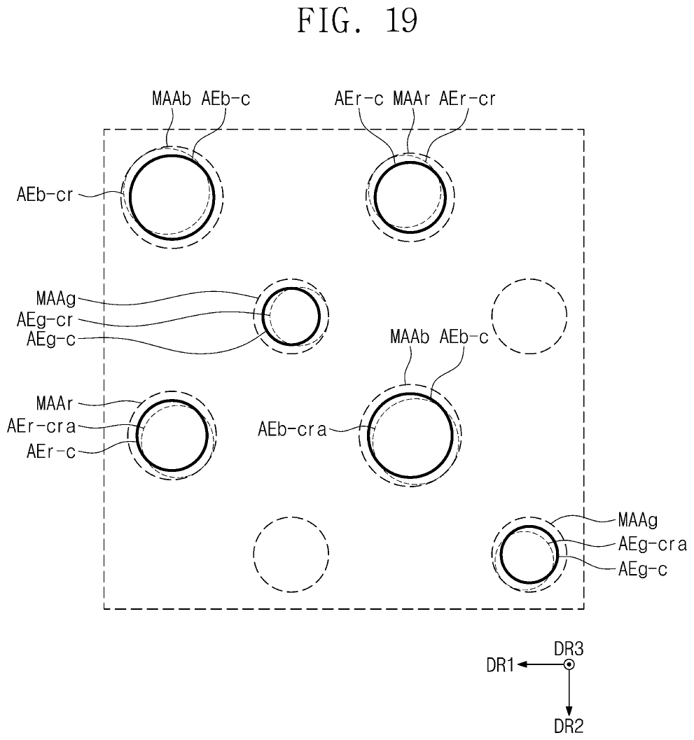

FIG. 19 is a schematic plan view for describing a random arrangement according to an embodiment.

Referring to FIG. 19, the sizes of mask openings MAAr, MAAg, and MAAb may be greater than the sizes of pixel electrodes AEr-c, AEb-c, and AEg-c. Since the sizes of mask openings MAAr, MAAg, and MAAb are determined in consideration of a design margin, the sizes of mask openings MAAr, MAAg, and MAAb may be greater than the sizes of pixel electrodes AEr-c, AEg-c, and AEb-c.

According to an embodiment, an additional random structure may be implemented by shifting the positions of the pixel electrodes AEr-c, AEg-c, and AEb-c and the positions of the pixel defining pattern layers PDL2 (refer to FIG. 17B) from the center portions of the mask openings MAAr, MAAg, and MAAb. The pixel defining pattern layers PDL2 may cover edge portions of the pixel electrodes AEr-c, AEg-c, and AEb-c. Accordingly, the positions of the pixel defining pattern layers PDL2 may also be changed in response to the change in the positions of the pixel electrodes AEr-c, AEg-c, and AEb-c.

In FIG. 19, the pixel electrodes AEr-c, AEg-c, and AEb-c disposed at the center portions of the mask openings MAAr, MAAg, and MAAb are illustrated by solid lines, and shifted pixel electrodes AEr-cr, AEr-cra, AEg-cr, AEg-cra, AEb-cr, and AEb-cra are illustrated by dotted lines. According to an embodiment, the first type light emitting units EU1 may include at least two light emitting units having different arrangement rules (or patterns), and the pixel electrodes AEr-cr, AEr-cra, AEg-cr, AEg-cra, AEb-cr, and AEb-cra may be applied in a structure shifted from the center portion within the pixel electrodes included in each of the light emitting units. Accordingly, the degree of randomness may be further increased. Thus, a light blurring phenomenon and a double image due to a regular arrangement may be improved. As a result, the quality of an image obtained by the camera module CMM (refer to FIG. 2A) may be improved.

As described above, the first type light emitting units disposed in the first sub-region overlapping the camera module may include at least two light emitting units having different arrangement rules (or patterns). Accordingly, the light emitting elements disposed in the first sub-region may be implemented in a random arrangement structure that is able to be designed and manufactured. Thus, a light blurring phenomenon due to a regular arrangement may be alleviated or eliminated. Also, a double image may be eliminated, the spacing of the double image may be decreased, or the unnecessary clarity of the double image may be reduced. As a result, the quality of an image obtained by the camera module may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An electronic device comprising:
a display panel including a first region and a second region adjacent to the first region, wherein
the display panel includes:
a first light emitting unit disposed in the first region, the first light emitting unit including (1-1)th light emitting elements, (1-2)th light emitting elements, and (1-3)th light emitting elements; and
a second light emitting unit disposed in the first region, the second light emitting unit including (2-1)th light emitting elements, (2-2)th light emitting elements, and (2-3)th light emitting elements,
the (1-1)th light emitting elements and the (2-1)th light emitting elements have a same arrangement pattern,
the (1-3)th light emitting elements and the (2-3)th light emitting elements have a same arrangement pattern, and
the (1-2)th light emitting elements and the (2-2)th light emitting elements have different arrangement patterns.

2. The electronic device of claim 1, wherein the display panel further includes:
a (1-1)th pixel circuit electrically connected to the (1-1)th light emitting elements;
a (1-2)th pixel circuit electrically connected to the (1-2)th light emitting elements; and
a (1-3)th pixel circuit electrically connected to the (1-3)th light emitting elements.

3. The electronic device of claim 2, wherein
the first region includes:
a first sub-region;
a second sub-region surrounding the first sub-region, the second sub-region having a light transmittance lower than a light transmittance of the first sub-region;
a plurality of third sub-regions spaced apart from each other, the second sub-region disposed between the plurality of third sub-regions; and
a fourth sub-region surrounding the second sub-region and the plurality of third sub-regions, and
the second region surrounds the fourth sub-region.

4. The electronic device of claim 3, wherein
the first light emitting unit and the second light emitting unit are disposed in the first sub-region, and
the (1-1)th pixel circuit, the (1-2)th pixel circuit, and the (1-3)th pixel circuit are disposed in the plurality of third sub-regions, respectively.

5. The electronic device of claim 3, wherein the first sub-region includes:
a first zone in which the first light emitting unit is disposed, and
a second zone in which the second light emitting unit is disposed.

6. The electronic device of claim 5, wherein the second zone surrounds the first zone.

7. The electronic device of claim 3, wherein
the display panel further includes a plurality of intermediate light emitting units disposed in the second sub-region, the plurality of third sub-regions, and the fourth sub-region, respectively,
each of the plurality of intermediate light emitting units includes (3-1)th light emitting elements, (3-2)th light emitting elements, and (3-3)th light emitting elements,
the number of the (1-1)th light emitting elements is equal to the number of the (3-1)th light emitting elements,
the number of the (1-3)th light emitting elements is equal to the number of the (3-3)th light emitting elements, and
the number of the (1-2)th light emitting elements is smaller than the number of the (3-2)th light emitting elements.

8. The electronic device of claim 1, wherein
the display panel further includes a main light emitting unit disposed in the second region,
the main light emitting unit includes first light emitting elements, second light emitting elements, and third light emitting elements, and
the number of the second light emitting elements is greater than the number of the (1-2)th light emitting elements.

9. The electronic device of claim 8, wherein
the display panel further includes a plurality of main pixel circuits, and
the first light emitting elements, the second light emitting elements, and the third light emitting elements are electrically connected to the plurality of main pixel circuits in a one-to-one manner.

10. The electronic device of claim 1, wherein a first point, a second point spaced apart from the first point in a first direction, a third point spaced apart from the first point in a second direction intersecting the first direction, a fourth point spaced apart from the third point in the first direction, a first selection point disposed between the first to fourth points, a second selection point spaced apart from the first selection point in the first direction, a third selection point spaced apart from the first selection point in the second direction, and a fourth selection point spaced apart from the third selection point in the first direction are defined in each of the first light emitting unit and the second light emitting unit.

11. The electronic device of claim 10, wherein
the (1-1)th light emitting elements are disposed at the second point and the third point of the first light emitting unit,
the (1-2)th light emitting elements are disposed at two selection points selected from the first to fourth selection points of the first light emitting unit,
the (1-3)th light emitting elements are disposed at the first point and the fourth point of the first light emitting unit,
the (2-1)th light emitting elements are disposed at the second point and the third point of the second light emitting unit,
the (2-2)th light emitting elements are disposed at two selection points selected from the first to fourth selection points of the second light emitting unit, and
the (2-3)th light emitting elements are disposed at the first point and the fourth point of the second light emitting unit.

12. The electronic device of claim 11, wherein
the two selection points overlapping the (1-2)th light emitting elements correspond to one of six combinations formed with the first to fourth selection points, and
the two selection points overlapping the (2-2)th light emitting elements correspond to another one of the six combinations.

13. The electronic device of claim 12, wherein
the display panel further includes at least one of a third light emitting unit disposed in the first region, a fourth light emitting unit disposed in the first region, a fifth light emitting unit disposed in the first region, and a sixth light emitting unit disposed in the first region, and
an arrangement pattern of light emitting elements included in the third to sixth light emitting units corresponds to each of the remaining four combinations of the six combinations.

14. The electronic device of claim 1, wherein
the (1-1)th light emitting elements and the (2-1)th light emitting elements are red light emitting elements,
the (1-2)th light emitting elements and the (2-2)th light emitting elements are green light emitting elements, and
the (1-3)th light emitting elements and the (2-3)th light emitting elements are blue light emitting elements.

15. The electronic device of claim 1, further comprising:
a camera module disposed under the first region of the display panel,
wherein a plurality of transmissive regions are defined in the first region.

16. An electronic device comprising:
a display panel including a first light emitting unit including six first arrangement light emitting elements and a second light emitting unit including six second arrangement light emitting elements, wherein
a first point, a second point spaced apart from the first point in a first direction, a third point spaced apart from the first point in a second direction intersecting the first direction, a fourth point spaced apart from the third point in the first direction, a first selection point disposed between the first to fourth points, a second selection point spaced apart from the first selection point in the first direction, a third selection point spaced apart from the first selection point in the second direction, and a fourth selection point spaced apart from the third selection point in the first direction are defined in each of the first light emitting unit and the second light emitting unit,
among the first arrangement light emitting elements, four first arrangement light emitting elements are disposed at the first to fourth points, and two first arrangement light emitting elements are disposed at two selection points of a first combination among the first to fourth selection points, and
among the second arrangement light emitting elements, four second arrangement light emitting elements are disposed at the first to fourth points, and two second arrangement light emitting elements are disposed at two selection points of a second combination different from the first combination among the first to fourth selection points.

17. The electronic device of claim 16, wherein
a first region and a second region adjacent to the first region and having a light transmittance lower than a light transmittance of the first region are defined in the display panel,
the first region includes:
a first sub-region;
a second sub-region surrounding the first sub-region, the second sub-region having a light transmittance lower than a light transmittance of the first sub-region;
a plurality of third sub-regions spaced apart from each other, the second sub-region between the plurality of third sub-regions; and
a fourth sub-region surrounding the second sub-region and the plurality of third sub-regions, and
the first light emitting unit and the second light emitting unit are disposed in the first sub-region.

18. The electronic device of claim 17, wherein the first sub-region includes:
a first zone in which the first light emitting unit is disposed, and
a second zone in which the second light emitting unit is disposed.

19. The electronic device of claim 17, wherein
the display panel further includes:
three first pixel circuits electrically connected to the first light emitting unit; and
three second pixel circuits electrically connected to the second light emitting unit, and
the first pixel circuits and the second pixel circuits are disposed in the plurality of third sub-regions, respectively.

20. The electronic device of claim 17, wherein
the display panel further includes:
an intermediate light emitting unit disposed in the second sub-region, the plurality of third sub-regions, or the fourth sub-region, the intermediate light emitting unit including eight intermediate light emitting elements; and
three third pixel circuits electrically connected to the intermediate light emitting unit.

21. An electronic device comprising:
a display panel including a first region and a second region adjacent to the first region, wherein
the first region includes a first sub-region including a transmissive region and a second sub-region spaced apart from the first sub-region,
the display panel includes:
a first light emitting unit disposed in the first sub-region, the first light emitting unit including first green light emitting elements arranged according to a first arrangement pattern;
a second light emitting unit disposed in the first sub-region, the second light emitting unit including second green light emitting elements arranged according to a second arrangement pattern different from the first arrangement pattern;
a first pixel circuit disposed in the second sub-region and electrically connected to the first green light emitting elements; and
a second pixel circuit disposed in the second sub-region and electrically connected to the second green light emitting elements.

22. The electronic device of claim 21, wherein
the first light emitting unit further includes first blue light emitting elements and first red light emitting elements,
the second light emitting unit further includes second blue light emitting elements and second red light emitting elements,
the first blue light emitting elements and the second blue light emitting elements are arranged according to a same arrangement pattern, and
the first red light emitting elements and the second red light emitting elements are arranged according to a same arrangement pattern.
